(19) United States
(12) Patent Application Publication
(10) Pub. No.: US 2026/0061521 A1
(43) Pub. Date: Mar. 5, 2026

(54) APPARATUS FOR MANUFACTURING DISPLAY DEVICE AND METHOD FOR MANUFACTURING DISPLAY DEVICE

(71) Applicant: Samsung Display Co., LTD., Yongin-si (KR)

(72) Inventors: Kyu Bum KIM, Yongin-si (KR); Je Yun RYU, Yongin-si (KR); Jeong Su KIM, Yongin-si (KR); Hyun Sung PARK, Yongin-si (KR); Yeon Su LIM, Yongin-si (KR); Jin Won CHANG, Yongin-si (KR); Ho Jin JANG, Yongin-si (KR); Chu Jong JOO, Yongin-si (KR)

(21) Appl. No.: 19/216,126

(22) Filed: May 22, 2025

(30) Foreign Application Priority Data
Sep. 5, 2024 (KR) 10-2024-0120900

(51) Int. Cl. B23K 26/36; B23K 26/03; B23K 26/06; B23K 101/36; H10K 59/12

(52) U.S. Cl. CPC B23K 26/36; B23K 26/03; B23K 26/0604; B23K 26/0648; H10K 59/1201; B23K 2101/36

(57) ABSTRACT

An apparatus for manufacturing a display device includes a stage, a processing laser unit which generates a first laser toward the stage, a flatness sensing unit which generates a second laser toward the stage, a common optical system disposed in optical paths of the first laser and the second laser, and a thickness sensing unit which generates a third laser toward the stage, where the common optical system includes an objective lens through which both the first laser and the second laser pass.

This application claims priority to Korean Patent Application No. 10-2024-0120900, filed on Sep. 5, 2024, and all the benefits accruing therefrom under 35 U.S.C. § 119, the content of which in its entirety is incorporated herein by reference.

### BACKGROUND

### 1. Field

Embodiments of the disclosure relate to an apparatus for manufacturing a display device and a method for manufacturing a display device.

### 2. Description of the Related Art

With the advance of information-oriented society, display devices for displaying images are more widely used in various fields. A display device may be a flat panel display device such as a liquid crystal display, a field emission display and a light emitting display.

The display device includes a display area for displaying an image and a non-display area disposed around the display area, for example, to surround the display area. Recently, the width of the non-display area has been gradually reduced to increase immersion in the display area and enhance the aesthetics of the display device.

In a manufacturing process of the display device, the display device may be formed by cutting a mother substrate along a plurality of display cells formed on the mother substrate including the plurality of display cells.

The non-display area may include a first non-display area in which lines and circuits for driving the display area are disposed, and a second non-display area corresponding to a margin for a cutting process in a manufacturing process. Since there is a limit to reducing lines and circuits in the first non-display area, a method of reducing the width of the second non-display area is being researched.

A laser processing device may be used to cut the mother substrate. The laser processing device is a device that uses a laser beam to perform processing such as cutting, pattern formation, and welding of a material. The laser beam used in laser processing has the characteristics of strong directivity and high density. In particular, a high-power laser may be used to process a display panel since the high-power laser may not affect the surroundings and enable precise processing.

### SUMMARY

Embodiments of the disclosure provide an apparatus for manufacturing a display device and a method for manufacturing a display device, which are capable of correcting a laser focal distance in real time.

Embodiments of the disclosure also provide an apparatus for manufacturing a display device and a method for manufacturing a display device, which are capable of improving mass production quality and yield of the display device.

However, Embodiments of the disclosure are not restricted to those set forth herein. The above and other embodiments of the disclosure will become more apparent to one of ordinary skill in the art to which the disclosure pertains by referencing the detailed description of the disclosure given below.

According to an embodiment of the disclosure, an apparatus for manufacturing a display device includes a stage, a processing laser unit which generates a first laser toward the stage, a flatness sensing unit which generates a second laser toward the stage, a common optical system disposed in optical paths of the first laser and the second laser, and a thickness sensing unit which generates a third laser toward the stage, where the common optical system includes an objective lens through which both the first laser and the second laser pass.

In an embodiment, the common optical system may further include a beam splitter which transmits at least a portion of each of the first laser and the second laser and reflects another portion thereof, the processing laser unit may be disposed on one side of a first surface of the beam splitter, and the flatness sensing unit may be disposed on one side of a second surface of the beam splitter, which is different from the first surface thereof.

In an embodiment, a direction in which the first laser is incident on the beam splitter may be different from a direction in which the second laser is incident on the beam splitter.

In an embodiment, the objective lens may be disposed on one side of a third surface of the beam splitter, which is different from the first surface and the second surface thereof.

In an embodiment, the beam splitter may cause the first laser and the second laser, which are incident from different directions, to be emitted in a same direction.

In an embodiment, the common optical system may further include a beam dump which absorbs at least a portion of the first laser and the second laser, and the beam dump is disposed on one side of a fourth surface of the beam splitter, which is different from the first to third surfaces thereof.

In an embodiment, the beam splitter may include a prism or a half mirror.

In an embodiment, the common optical system may further include an objective driver which provides a driving force to the objective lens.

In an embodiment, the objective driver may move the objective lens to adjust focal positions of the first laser and the second laser.

In an embodiment, a separation distance between a focal position of the first laser and a focal position of the second laser may be equal to or less than about 50 micrometers (μm).

In an embodiment, a focal position of the second laser may be located on a top surface of the stage.

In an embodiment, a focal position of the third laser may be located on top and bottom surfaces of a target object.

In an embodiment, the flatness sensing unit may include an autofocus sensor.

In an embodiment, the thickness sensing unit may include a confocal sensor.

In an embodiment, a wavelength of the first laser may be greater than a wavelength of the second laser.

According to an embodiment of the disclosure, a method for manufacturing a display device includes measuring a thickness of a mother substrate by irradiating top and bottom surfaces of the mother substrate with a first sensing laser, measuring flatness of the mother substrate by irradiating the bottom surface of the mother substrate with a second sensing laser, correcting a focal position of a processing laser by adjusting a position of an optical system based on the measured thickness and flatness of the mother substrate, and forming a cutting line by irradiating the mother substrate with the processing laser, where the measuring the flatness, the correcting the focal position of the processing laser, and the forming the cutting line are performed simultaneously.

In an embodiment, both the second sensing laser and the processing laser may pass through the optical system.

In an embodiment, the measuring the flatness and the correcting the focal position of the processing laser may include tracking, by the second sensing laser, a curvature of the bottom surface of the mother substrate in real time to adjust a position of the optical system, and the focal position of the processing laser is adjusted together with the position of the optical system.

In an embodiment, the focal position the processing laser may be synchronized with a focal position of the second sensing laser through the optical system.

In an embodiment, the position of the optical system may be corrected based on a change in the focal position of the second sensing laser, and the focal position of the processing laser is corrected together with a correction of the position of the optical system.

In the apparatus for manufacturing a display device and the method of manufacturing a display device according to embodiments of the disclosure, it is possible to correct a laser focal distance in real time.

In the apparatus for manufacturing a display device and the method of manufacturing a display device according to embodiments of the disclosure, it is possible to improve mass production quality and yield of the display device.

It should be noted that effects of the disclosure are not limited to those described above and other effects of the disclosure will be apparent to those skilled in the art from the following descriptions.

### BRIEF DESCRIPTION OF THE DRAWINGS

The above and other features of embodiments of the disclosure will become more apparent by describing in detail embodiments thereof with reference to the attached drawings, in which:

FIG. 1 is a perspective view showing a display device according to an embodiment;

FIG. 2 is a plan view illustrating a display panel and a driving IC according to an embodiment;

FIG. 3 is a cross-sectional view taken along lines XA-XA′ and XB-XB′ of FIG. 1;

FIG. 4 is a cross-sectional view showing the display device of FIG. 3 in a bent state;

FIG. 5 is a cross-sectional view illustrating an example of a display area of a display panel according to an embodiment;

FIG. 6 is an enlarged view of area A of FIG. 2;

FIG. 7 is a cross-sectional view showing an example of a display panel taken along line XC-XC′ of FIG. 6;

FIG. 8 is a cross-sectional view showing another example of a display panel taken along line XC-XC′ of FIG. 6;

FIG. 9 is an enlarged view of area C of FIG. 7;

FIG. 10 is an enlarged view of area B of FIG. 2;

FIG. 11 is a cross-sectional view taken along line XD-XD′ of FIG. 10;

FIG. 12 is an enlarged view of area D of FIG. 11;

FIG. 13 is a flowchart showing a method for manufacturing a display device according to an embodiment;

FIG. 14 is a cross-sectional view showing display cells and a region interposed therebetween in process S100 of FIG. 13;

FIG. 15 is a cross-sectional view showing display cells and a region interposed therebetween in process S200 of FIG. 13;

FIG. 16 is a cross-sectional view showing display cells and a region interposed therebetween in process S300 of FIG. 13;

FIGS. 17 and 18 are cross-sectional views showing display cells and a region interposed therebetween in process S400 of FIG. 13;

FIG. 19 is a cross-sectional view showing hole dams and a region interposed therebetween in process S100 of FIG. 13;

FIG. 20 is a cross-sectional view showing hole dams and a region interposed therebetween in process S200 of FIG. 13;

FIG. 21 is a cross-sectional view showing hole dams and a region interposed therebetween in process S300 of FIG. 13;

FIGS. 22 and 23 are cross-sectional views showing hole dams and a region interposed therebetween in process S400 of FIG. 13;

FIG. 24 is a cross-sectional view showing an apparatus for manufacturing a display device according to an embodiment;

FIG. 25 is a cross-sectional view illustrating an operating state of a thickness sensing unit according to an embodiment;

FIG. 26 is a cross-sectional view illustrating a thickness sensing method of a thickness sensing unit according to an embodiment;

FIG. 27 is a cross-sectional view illustrating an operating state of a flatness sensing unit according to an embodiment;

FIG. 28 is a cross-sectional view illustrating an operating state of a processing laser unit according to an embodiment;

FIG. 29 is a cross-sectional view illustrating operating states of a flatness sensing unit and a processing laser unit according to an embodiment;

FIG. 30 is a cross-sectional view illustrating the traveling paths of a sensing laser of a flatness sensing unit and a processing laser of a processing laser unit according to an embodiment; and

FIG. 31 is a cross-sectional view illustrating a flatness sensing method of a flatness sensing unit according to an embodiment.

### DETAILED DESCRIPTION

The invention will now be described more fully hereinafter with reference to the accompanying drawings, in which various embodiments are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will also be understood that when a layer is referred to as being “on” another layer or substrate, it can be directly on the other layer or substrate, or intervening layers may also be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

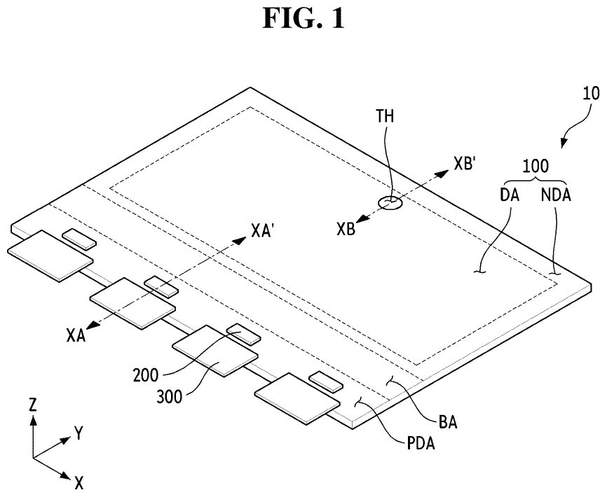

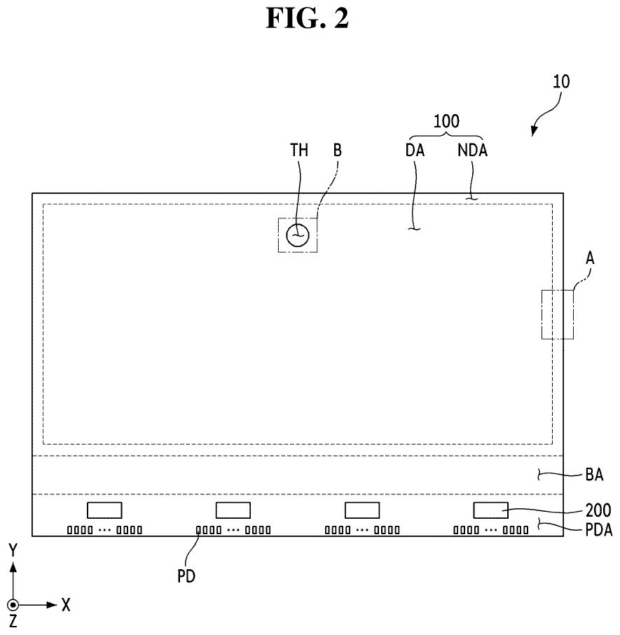

FIG. 1 is a perspective view showing a display device according to an embodiment. FIG. 2 is a plan view illustrating a display panel and a driving IC according to an embodiment.

Referring to FIGS. 1 and 2, an embodiment of a display device 10, which is a device for displaying a moving image or a still image, may be used to provide a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 according to an embodiment may be a light emitting display device such as an organic light emitting display using an organic light emitting diode, a quantum dot light emitting display including a quantum dot light emitting layer, an inorganic light emitting display including an inorganic semiconductor, or a micro or nano light emitting display using a micro or nano light emitting diode (LED). Hereinafter, for convenience of description, embodiments where the display device 10 is an organic light emitting display device will be mainly described, but the disclosure is not limited thereto.

The display device 10 according to an embodiment may include a display panel 100, a driving integrated circuit (IC) 200, and a circuit board 300.

The display panel 100 may be formed in a rectangular shape, in a plan view, having long sides in a first direction (X-axis direction) and short sides in a second direction (Y-axis direction) crossing the first direction (X-axis direction). A corner formed by the long side in the first direction (X-axis direction) and the short side in the second direction (Y-axis direction) may be right-angled or rounded with a curvature. The planar shape of the display panel 100 is not limited to the rectangular shape, and may be formed in another polygonal shape, a circular shape or an elliptical shape.

In the disclosure, the first direction (X-axis direction) and the second direction (Y-axis direction) cross each other as horizontal directions. For example, the first direction (X-axis direction) and the second direction (Y-axis direction) may be orthogonal to each other. In addition, a third direction (Z-axis direction) crosses the first direction (X-axis direction) and the second direction (Y-axis direction), and the first to third directions may be, for example, perpendicular directions orthogonal to each other. In the disclosure, directions indicated by arrows of the first to third directions (X-axis direction, Y-axis direction, and Z-axis direction) may be referred to as one side, and the opposite directions thereto may be referred to as the other side.

In an embodiment, the display panel 100 may be formed to be flat, but is not limited thereto. In another embodiment, for example, the display panel 100 may include a curved portion formed at left and right ends and having a constant curvature or a varying curvature. In another embodiment, the display panel 100 may be formed flexibly such that the display panel 100 can be curved, bent, folded, or rolled.

The display panel 100 may include a display area DA for displaying an image and a non-display area NDA disposed around the display area DA.

The display area DA may occupy most of the area of the display panel 100. The display area DA may be disposed at the center of the display panel 100. Pixels each including a plurality of emission areas may be disposed in the display area DA to display an image.

The non-display area NDA may be disposed adjacent to the display area DA. The non-display area NDA may be an area outside the display area DA. The non-display area NDA may be disposed to surround the display area DA. The non-display area NDA may be an edge area of the display panel 100.

The non-display area NDA may include a bending area BA and a pad area PDA.

The bending area BA may be disposed between the display area DA and the pad area PDA in the second direction (Y-axis direction). The bending area BA may extend in the first direction (X-axis direction). The bending area BA refers to an area that bends toward the bottom of the display panel 100. When the bending area BA bends toward the bottom of the display panel 100, the plurality of driving ICs 200 and the circuit board 300 may be disposed below the display panel 100.

The pad area PDA may be a lower edge area of the display panel 100. The pad area PDA may be the area where display pads PD connected to the circuit board 300 and driving pads connected to the driving IC 200 are disposed.

The display pads DP may be arranged in the pad area PDA to be connected to the circuit boards 300. The display pads DP may be disposed on one side edge of the display panel 100. In an embodiment, for example, the display pads DP may be disposed at the lower edge of the display panel 100.

The driving ICs 200 may generate the data voltages, the source voltages, the scan timing signals, and the like. The driving ICs 200 may output the data voltages, the source voltages, the scan timing signals, and the like.

The driving ICs 200 may be disposed in the pad area PDA. The driving ICs 200 may be disposed between the display pads PD and the display area DA in the non-display area NDA. Each of the driving ICs 200 may be attached to the non-display area NDA of the display panel 100 in a chip on glass (COG) method. Alternatively, each of the driving ICs 200 may be attached to the circuit board 300 in a chip on plastic (COP) method.

The circuit boards 300 may be disposed on the display pads DP disposed on one side edge of the display panel 100. The circuit boards 300 may be attached to the display pads PD by using a conductive adhesive member such as an anisotropic conductive film and an anisotropic conductive adhesive. Accordingly, the circuit boards 300 may be electrically connected to the signal lines of the display panel 100. The circuit boards 300 may be a flexible printed circuit board or a flexible film such as a chip on film.

A through hole TH may be defined on one side of the display area DA. The through hole TH may be a hole capable of transmitting light, and may be an area where an optical device is disposed.

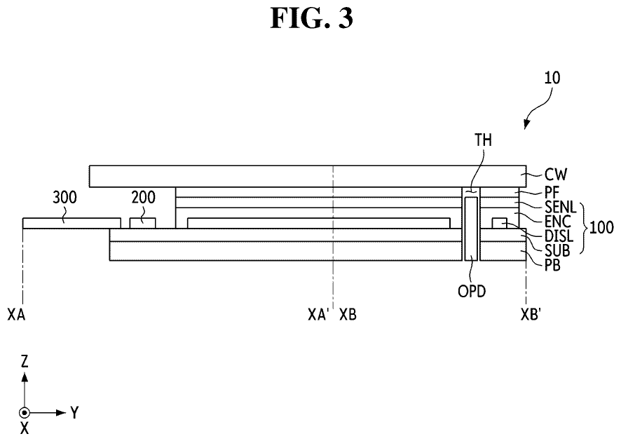

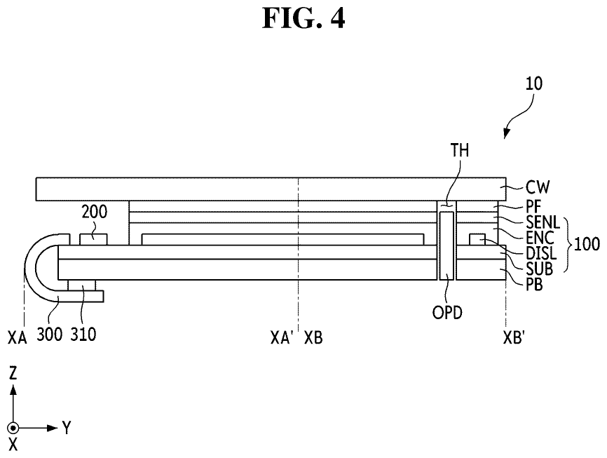

FIG. 3 is a cross-sectional view taken along lines XA-XA′ and XB-XB′ of FIG. 1. FIG. 4 is a cross-sectional view showing the display device of FIG. 3 in a bent state.

Referring to FIGS. 3 and 4, the display device 10 according to an embodiment may include the display panel 100, a polarizing film PF, a cover window CW, and a panel lower cover PB. The display panel 100 may include a substrate SUB, a display layer DISL, an encapsulation layer ENC, and a sensor electrode layer SENL.

The substrate SUB may include a hard or rigid material. In an embodiment, for example, the substrate SUB may include or be made of glass. The substrate SUB may be formed of or defined by an ultra thin glass (UTG) having a thickness of about 200 micrometers (μm) or less.

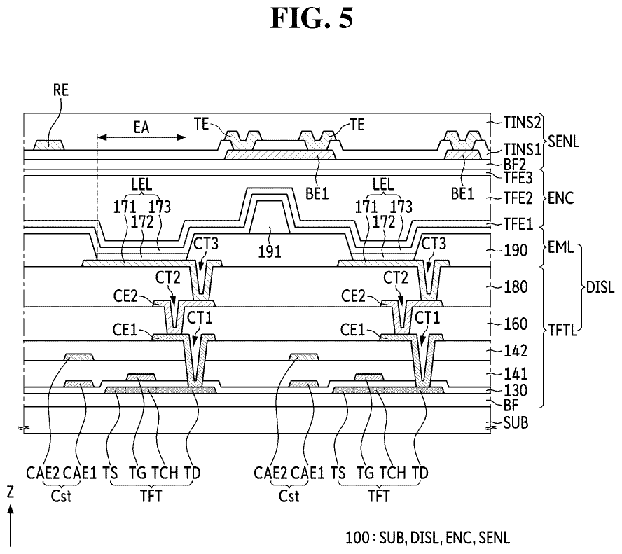

The display layer DISL may be disposed on the first surface of the substrate SUB. The display layer DISL may be a layer for displaying an image. The display layer DISL may include a thin film transistor layer TFTL (see FIG. 5) in which thin film transistors are formed, and a light emitting element layer EML (see FIG. 5) in which light emitting elements emitting light are disposed in the emission areas.

In the display area DA of the display layer DISL, scan lines, data lines, power lines, or the like for the emission areas to emit light may be disposed. In the non-display area NDA of the display layer DISL, a scan driving circuit unit for outputting scan signals to the scan lines, fan-out lines connecting the data lines and the driving IC 200, or the like may be disposed.

The encapsulation layer ENC may be a layer for encapsulating the light emitting element layer of the display layer DISL to prevent permeation of oxygen or moisture into the light emitting element layer of the display layer DISL. The encapsulation layer ENC may be disposed on the display layer DISL. The encapsulation layer ENC may be disposed on the top surfaces and the side surfaces of the display layer DISL. The encapsulation layer ENC may be disposed to cover the display layer DISL.

The sensor electrode layer SENL may be disposed on the display layer DISL. The sensor electrode layer SENL may include sensor electrodes. The sensor electrode layer SENL may sense a user's touch using sensor electrodes.

The polarizing film PF may be disposed on the sensor electrode layer SENL. The polarizing film PF may be disposed on the display panel 100 to reduce reflection of external light. The polarizing film PF may include a first base member, a linear polarization plate, a phase retardation film such as a quarter-wave plate (24 plate), and a second base member. The first base member, the phase retardation film, the linear polarization plate, and the second base member of the polarizing film PF may be sequentially stacked on the display panel 100.

The cover window CW may be disposed on the polarizing film PF. The cover window CW may be attached onto the polarizing film PF by a transparent adhesive member such as an optically clear adhesive (OCA) film.

The panel lower cover PB may be disposed on a second surface of the substrate SUB of the display panel 100. The second surface of the substrate SUB may be a surface opposite to the first surface. The panel lower cover PB may be attached to the second surface of the substrate SUB of the display panel 100 through an adhesive member. The adhesive member may be a pressure sensitive adhesive (PSA).

The panel lower cover PB may include at least one selected from a light blocking member for absorbing light incident from the outside, a buffer member for absorbing an impact from the outside, or a heat dissipation member for efficiently dissipating heat from the display panel 100.

The driving IC 200 and the circuit board 300 may be bent downward of the display panel 100. The circuit board 300 may be attached to the bottom surface of the panel lower cover PB by an adhesive member 310. The adhesive member 310 may be a pressure sensitive adhesive.

The through hole TH may be defined in the display device 10 according to an embodiment. The through hole TH may be a hole capable of transmitting light, and may be a physical hole penetrating not only the display panel 100 but also the panel lower cover PB and the polarizing film PF. In an embodiment, for example, the through hole TH may be defined or formed through the substrate SUB, the display layer DISL, the encapsulation layer ENC, and the sensor electrode layer SENL of the display panel 100. However, the disclosure is not limited thereto, and the through hole TH may be defined or formed through the panel lower cover PB but may not extend through the display panel 100 and the polarizing film PF. The cover window CW may be disposed to cover the through hole TH.

An electronic device including the display device 10 according to an embodiment may further include an optical device OPD disposed in the through hole TH. The optical device OPD may be spaced apart from the display panel 100, the panel lower cover PB, and the polarizing film PF. The optical device OPD may be an optical sensor that senses light incident through the through hole TH, such as a proximity sensor, an illuminance sensor, and a camera sensor.

FIG. 5 is a cross-sectional view illustrating an example of a display area of a display panel according to an embodiment.

Referring to FIG. 5, the display panel 100 according to an embodiment may be an organic light emitting display panel including a light emitting element LEL including an organic light emitting layer 172. The display layer DISL may include the thin film transistor layer TFTL including a plurality of thin film transistors and the light emitting element layer EML including a plurality of light emitting elements.

The substrate SUB may have a hard or rigid material. In an embodiment, for example, the substrate SUB may include or be made of glass. The substrate SUB may be formed of or defined by an UTG having a thickness of about 200 μm or less.

A buffer film BF may be disposed on the substrate SUB. The buffer film BF may include or be formed of an inorganic material such as a silicon nitride layer, a silicon oxynitride layer, a silicon oxide layer, a titanium oxide layer and an aluminum oxide layer. Alternatively, the buffer film BF may be formed as or defined by a multilayer in which a plurality of layers selected from a silicon nitride layer, a silicon oxynitride layer, a silicon oxide layer, a titanium oxide layer and an aluminum oxide layer are alternately stacked.

An active layer including a channel region TCH, a source region TS, and a drain region TD of a thin film transistor TFT may be disposed on the buffer film BF. The active layer may include or be formed of polycrystalline silicon, monocrystalline silicon, low-temperature polycrystalline silicon, amorphous silicon, or an oxide semiconductor material. In an embodiment where the active layer includes polycrystalline silicon or an oxide semiconductor material, the source region TS and the drain region TD of the active layer may be conductive regions doped with ions or impurities and having conductivity.

The gate insulating film 130 may be disposed on the active layer of the thin film transistor TFT. The gate insulating film 130 may include or be formed of an inorganic film, for example, a silicon nitride layer, a silicon oxynitride layer, a silicon oxide layer, a titanium oxide layer, or an aluminum oxide layer.

A first gate metal layer including a gate electrode TG of the thin film transistor TFT, a first capacitor electrode CAE1 of a capacitor Cst, and scan lines may be disposed on the gate insulating film 130. The gate electrode TG of the thin film transistor TFT may overlap the channel region TCH in the third direction (Z-axis direction). The first gate metal layer may be formed as or defined by a single layer or multiple layers including at least one selected from molybdenum (Mo), aluminum (Al), chromium (Cr), gold (Au), titanium (Ti), nickel (Ni), neodymium (Nd) and copper (Cu) or an alloy thereof.

A first interlayer insulating film 141 may be disposed on the first gate metal layer. The first interlayer insulating film 141 may include or be formed of an inorganic film, for example, a silicon nitride layer, a silicon oxynitride layer, a silicon oxide layer, a titanium oxide layer, or an aluminum oxide layer. The first interlayer insulating film 141 may include a plurality of inorganic films.

A second gate metal layer including a second capacitor electrode CAE2 of the capacitor Cst may be disposed on the first interlayer insulating film 141. The second capacitor electrode CAE2 may overlap the first capacitor electrode CAE1 in the third direction (Z-axis direction). Therefore, the capacitor Cst may be formed or defined by the first capacitor electrode CAE1, the second capacitor electrode CAE2, and an inorganic insulating dielectric layer disposed therebetween to serve as a dielectric layer. The second gate metal layer may be formed as or defined by a single layer or multiple layers including at least one selected from molybdenum (Mo), aluminum (Al), chromium (Cr), gold (Au), titanium (Ti), nickel (Ni), neodymium (Nd) and copper (Cu) or an alloy thereof.

A second interlayer insulating film 142 may be disposed on the second gate metal layer. The second interlayer insulating film 142 may include or be formed of an inorganic film, for example, a silicon nitride layer, a silicon oxynitride layer, a silicon oxide layer, a titanium oxide layer, or an aluminum oxide layer. The second interlayer insulating film 142 may include a plurality of inorganic films.

The first data metal layer including a first connection electrode CE1 and the data lines may be disposed on the second interlayer insulating film 142. The first connection electrode CE1 may be connected to the drain region TD through a first contact hole CT1 penetrating the gate insulating film 130, the first interlayer insulating film 141, and the second interlayer insulating film 142. The first data metal layer may be formed as or defined by a single layer or multiple layers including at least one selected from molybdenum (Mo), aluminum (Al), chromium (Cr), gold (Au), titanium (Ti), nickel (Ni), neodymium (Nd) and copper (Cu) or an alloy thereof.

A first organic film 160 for flattening the stepped portion due to the thin film transistors TFT may be disposed on the first connection electrode CE1. The first organic film 160 may include or be formed of an organic film such as acryl resin, epoxy resin, phenolic resin, polyamide resin, polyimide resin and the like.

The second data metal layer including a second connection electrode CE2 may be disposed on the first organic film 160. The second data metal layer may be connected to the first connection electrode CE1 through a second contact hole CT2 defined or formed through the first organic film 160. The second data metal layer may be formed as or defined by a single layer or multiple layers including at least one selected from molybdenum (Mo), aluminum (Al), chromium (Cr), gold (Au), titanium (Ti), nickel (Ni), neodymium (Nd) and copper (Cu) or an alloy thereof.

A second organic film 180 may be disposed on the second connection electrode CE2. The second organic film 180 may include or be formed of an organic film such as acryl resin, epoxy resin, phenolic resin, polyamide resin, polyimide resin and the like.

In an embodiment, the second data metal layer including the second connection electrode CE2 and the second organic film 180 may be omitted.

The light emitting element layer EML is disposed on the thin film transistor layer TFTL. The light emitting element layer EML may include light emitting elements LEL and a bank 190.

Each of the light emitting elements LEL may include a pixel electrode 171, a light emitting layer 172, and a common electrode 173. Each of the emission areas EA is an area in which the pixel electrode 171, the light emitting layer 172, and the common electrode 173 are sequentially stacked such that the holes from the pixel electrode 171 and the electrons from the common electrode 173 are combined with each other to emit light. In this case, the pixel electrode 171 may be an anode electrode, and the common electrode 173 may be a cathode electrode.

A pixel electrode layer including the pixel electrode 171 may be formed or disposed on the second organic film 180. The pixel electrode 171 may be connected to the second connection electrode CE2 through a third contact hole CT3 defined or formed through the second organic film 180. The pixel electrode layer may be formed as a single layer or multiple layers including at least one selected from molybdenum (Mo), aluminum (Al), chromium (Cr), gold (Au), titanium (Ti), nickel (Ni), neodymium (Nd) and copper (Cu) or an alloy thereof.

In an embodiment having a top emission structure that emits light toward the common electrode 173 with respect to the light emitting layer 172, the pixel electrode 171 may include or be formed of a single layer of molybdenum (Mo), titanium (Ti), copper (Cu), or aluminum (Al), or may be formed to have a stacked structure (Ti/Al/Ti) of aluminum and titanium, a stacked structure (ITO/AI/ITO) of aluminum and ITO, an APC alloy, or a stacked structure (ITO/APC/ITO) of APC alloy and ITO to increase the reflectivity. The APC alloy is an alloy of silver (Ag), palladium (Pd) and copper (Cu).

The bank 190 serves to define the emission areas EA of the pixels. In an embodiment, the bank 190 may expose a partial region of the pixel electrode 171 on the second organic film 180. The bank 190 may cover the edge of the pixel electrode 171. The bank 190 may be disposed in the third contact hole CT3 That is, the third contact hole CT3 may be filled with the bank 190. The bank 190 may include or be formed of an organic film such as acryl resin, epoxy resin, phenolic resin, polyamide resin, polyimide resin and the like.

A spacer 191 may be disposed on the bank 190. The spacer 191 may serve to support a mask during a process of manufacturing the light emitting layer 172. The spacer 191 may include or be formed of an organic film such as acryl resin, epoxy resin, phenolic resin, polyamide resin, polyimide resin and the like.

The light emitting layer 172 is formed or disposed on the pixel electrode 171. The light emitting layer 172 may include an organic material to emit light in a predetermined color. In an embodiment, for example, the light emitting layer 172 may include a hole transporting layer, an organic material layer, and an electron transporting layer. The organic material layer may include a host and a dopant. The organic material layer may include a material that emits predetermined light, and may be formed using a phosphorescent material or a fluorescent material.

The common electrode 173 is formed or disposed on the light emitting layer 172. The common electrode 173 may be formed to cover the light emitting layer 172. The common electrode 173 may be a common layer which is commonly formed in the emission areas EA1, EA2, EA3, and EA4. A capping layer may be formed or disposed on the common electrode 173.

In an embodiment having the top emission structure, the common electrode 173 may include or be formed of a transparent conductive material (TCO) such as ITO or IZO capable of transmitting light or a semi-transmissive conductive material such as magnesium (Mg), silver (Ag), or an alloy of magnesium (Mg) and silver (Ag). In such an embodiment where the common electrode 173 is formed of a semi-transmissive conductive material, the light emission efficiency can be increased due to a micro-cavity effect.

The encapsulation layer ENC may be disposed on the light emitting element layer EML. The encapsulation layer ENC may include at least one inorganic film TFE1 and TFE3 to prevent oxygen or moisture from permeating into the light emitting element layer EML. In addition, the encapsulation layer ENC may include at least one organic film TFE2 to protect the light emitting element layer EML from foreign substances such as dust. In an embodiment, for example, the encapsulation layer ENC may include a first encapsulation inorganic film TFE1, an encapsulation organic film TFE2, and a second encapsulation inorganic film TFE3.

The first encapsulation inorganic film TFE1 may be disposed on the common electrode 173, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed of or defined by multiple films in which one or more inorganic films of a silicon nitride layer, a silicon oxynitride layer, a silicon oxide layer, a titanium oxide layer and an aluminum oxide layer are alternately stacked. The encapsulation organic film TFE2 may be an organic film such as acryl resin, epoxy resin, phenolic resin, polyamide resin, polyimide resin or the like.

The sensor electrode layer SENL may be disposed on the encapsulation layer ENC. The sensor electrode layer SENL may include sensor electrodes TE and RE.

The second buffer film BF2 may be disposed on the encapsulation layer ENC. The second buffer film BF2 may include at least one inorganic film. In an embodiment, for example, the second buffer film BF2 may be formed of multiple films in which one or more inorganic films of a silicon nitride layer, a silicon oxynitride layer, a silicon oxide layer, a titanium oxide layer and an aluminum oxide layer are alternately stacked. In another embodiment, the second buffer film BF2 may be omitted.

The first connection portions BE1 may be disposed on the second buffer film BF2. The first connection portions BE1 may be formed of or defined by a single layer containing molybdenum (Mo), titanium (Ti), copper (Cu), or aluminum (Al), or may be formed to have a stacked structure (Ti/Al/Ti) of aluminum and titanium, a stacked structure (ITO/AI/ITO) of aluminum and indium tin oxide (ITO), an Ag—Pd—Cu (APC) alloy, or a stacked structure (ITO/APC/ITO) of APC alloy and ITO.

The first sensor insulating film TINS1 may be disposed on the first connection portions BE1. The first sensor insulating film TINS1 may include or be formed of an inorganic film, for example, a silicon nitride layer, a silicon oxynitride layer, a silicon oxide layer, a titanium oxide layer, or an aluminum oxide layer.

The sensor electrodes, that is, the driving electrodes TE and the sensing electrodes RE may be disposed on the first sensor insulating film TNIS1. In addition, dummy patterns may be disposed on the first sensor insulating film TNIS1. The driving electrodes TE, the sensing electrodes RE, and the dummy patterns do not overlap the emission areas EA. The driving electrodes TE, the sensing electrodes RE, and the dummy patterns may be formed of or defined by a single layer containing molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and indium tin oxide (ITO), an Ag-Pd—Cu (APC) alloy, or a stacked structure (ITO/APC/ITO) of APC alloy and ITO.

The second sensor insulating film TINS2 may be disposed on the driving electrodes TE, the sensing electrodes RE, and the dummy patterns. The second sensor insulating film TINS2 may include at least one selected from an inorganic film or an organic film. The inorganic film may be a silicon nitride layer, a silicon oxynitride layer, a silicon oxide layer, a titanium oxide layer, or an aluminum oxide layer. The organic film may include acryl resin, epoxy resin, phenolic resin, polyamide resin, or polyimide resin.

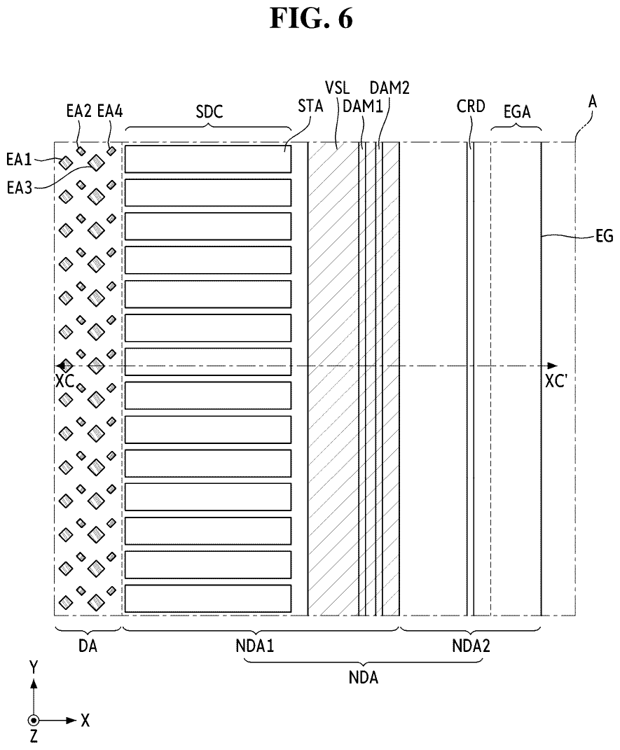

FIG. 6 is an enlarged view of area A of FIG. 2.

Referring to FIG. 6, the display area DA may include a plurality of emission areas EA1, EA2, EA3, and EA4. The plurality of emission areas EA1, EA2, EA3, and EA4 may include the first emission area EA1 that emits light of a first color, the second emission area EA2 and the fourth emission area EA4 that emits light of a second color, and the third emission area EA3 that emits light of a third color. In an embodiment, for example, light of the first color may be light in a red wavelength band of about 600 nanometers (nm) to about 750 nm, light of the second color may be light in a green wavelength band of about 480 nm to about 560 nm, and light of the third color may be light in a blue wavelength band of about 370 nm to about 460 nm, but the disclosure is not limited thereto.

Although FIG. 6 illustrates an embodiment where the second emission area EA2 and the fourth emission area EA4 emit light of the same color, that is, light of the second color, the disclosure is not limited thereto. The second emission area EA2 and the fourth emission area EA4 may emit light of different colors. In an embodiment, for example, the second emission area EA2 may emit light of the second color, and the fourth emission area EA4 may emit light of a fourth color.

In an embodiment, as shown in FIG. 6, each of the first emission areas EA1, the second emission areas EA2, the third emission areas EA3, and the fourth emission areas EA4 may have a rectangular planar shape, the disclosure is not limited thereto. In an embodiment, each of the first emission areas EA1, the second emission areas EA2, the third emission areas EA3, and the fourth emission areas EA4 may have a polygonal shape other than a quadrilateral shape, a circular shape, or an elliptical shape in a plan view.

The third emission area EA3 may have the largest area, and the second emission area EA2 and the fourth emission area EA4 may have the smallest areas. The size of the second emission area EA2 may be the same as the size of the fourth emission area EA4.

The second emission areas EA2 and the fourth emission areas EA4 may be alternately disposed in the first direction (X-axis direction). The second emission areas EA2 may be disposed in the second direction (Y-axis direction). The fourth emission areas EA4 may be disposed in the second direction (Y-axis direction). Each of the fourth emission areas EA4 may have a long side in a first diagonal direction and a short side in a second diagonal direction, while each of the second emission areas EA2 may have a long side in the second diagonal direction and a short side in the first diagonal direction. The first diagonal direction may refer to a diagonal direction between the first direction (X-axis direction) and the second direction (Y-axis direction), and the second diagonal direction may be a direction orthogonal to the first diagonal direction.

The first emission areas EA1 and the third emission areas EA3 may be alternately disposed in the first direction (X-axis direction). The first emission areas EA1 may be disposed in the second direction (Y-axis direction). The third emission areas EA3 may be disposed in the second direction (Y-axis direction). Each of the first emission areas EA1 and the third emission areas EA3 may have a square planar shape, but the disclosure is not limited thereto. In an embodiment, each of the first emission areas EA1 and the third emission areas EA3 may include two sides parallel to each other in the first diagonal direction and two sides parallel to each other in the second diagonal direction.

The non-display area NDA includes a first non-display area NDA1 and a second non-display area NDA2. The first non-display area NDA1 may be an area in which structures for driving pixels of the display area DA are disposed. The second non-display area NDA2 may be disposed outside the first non-display area NDA1. The second non-display area NDA2 may be an edge area of the non-display area NDA. In addition, the second non-display area NDA2 may be an edge area of the display panel 100.

A scan driving circuit unit SDC, a first power line VSL, a first dam DAM1, and a second dam DAM2 may be disposed in the first non-display area NDA1.

The scan driving circuit unit SDC may include a plurality of stages STA. The plurality of stages STA may be connected to scan lines of the display area DA extending in the first direction (X-axis direction), respectively. That is, the plurality of stages STA may be connected in a one-to-one correspondence to the scan lines of the display area DA extending in the first direction (X-axis direction). The plurality of stages STA may sequentially apply scan signals to the plurality of scan lines.

The first power line VSL may be disposed outside the scan driving circuit unit SDC. That is, the first power line VSL may be disposed closer to an edge EG of the display panel 100 than the scan driving circuit unit SDC. The first power line VSL may extend in the second direction (Y-axis direction) in the non-display area NDA on the right side of the display panel 100.

The first power line VSL may be electrically connected to the common electrode 173, so that the common electrode 173 may be supplied with the first source voltage from the first power line VSL.

The first dam DAM1 and the second dam DAM2 are structures for preventing the overflow of the encapsulation organic film TFE2 of the encapsulation layer ENC into the edge EG of the display panel 100. The first dam DAM1 and the second dam DAM2 may extend in the second direction (Y-axis direction) in the non-display area NDA on the right side of the display panel 100. The second dam DAM2 may be disposed outside the first dam DAM1. The first dam DAM1 may be disposed closer to the scan driving circuit unit SDC than the second dam DAM2, and the second dam DAM2 may be disposed closer to the edge EG of the display panel 100 than the first dam DAM1.

Although FIG. 6 illustrates an embodiment where the first dam DAM1 and the second dam DAM2 are disposed on the first power line VSL, the disclosure is not limited thereto. In another embodiment, for example, either one of the first dam DAM1 and the second dam DAM2 may not be disposed on the first power line VSL. Alternatively, neither the first dam DAM1 nor the second dam DAM2 may be disposed on the first power line VSL. In such an embodiment, the first dam DAM1 and the second dam DAM2 may be disposed outside the first power line VSL.

Although FIG. 6 illustrates an embodiment where the display panel 100 includes two dams DAM1 and DAM2, the embodiment of the specification is not limited thereto. That is, the display panel 100 according to another embodiment may include three or more dams.

The second non-display area NDA2 may include a crack dam CRD and an edge area EGA.

The crack dam CRD may be a structure for preventing cracks from occurring in a process of cutting the substrate SUB during the manufacturing process of the display device 10. The crack dam CRD may be an outermost structure disposed at the outermost portion of the display panel 100. The crack dam CRD may be disposed to surround the second dam DAM2 at the outermost portion of the display panel 100. In an embodiment, For example, as illustrated in FIG. 6, the crack dam CRD may extend in the second direction (Y-axis direction) in the non-display area NDA on the right side of the display panel 100. The crack dam CRD may be disposed closer to the edge EG than the second dam DAM2 in the second non-display area NDA2, and may be disposed between the second dam DAM2 and the edge area EGA.

Although not shown in the drawing, the crack dam CRD may extend in the first direction (X-axis direction) or the second direction (Y-axis direction) even at other outermost portions except for the right side of the display panel 100. Accordingly, the crack dam CRD may be disposed to surround the second dam DAM2.

The edge area EGA may be disposed along the edge EG of the display panel 100. The edge area EGA may be an area in which processing traces generated in a process of cutting the substrate SUB remain.

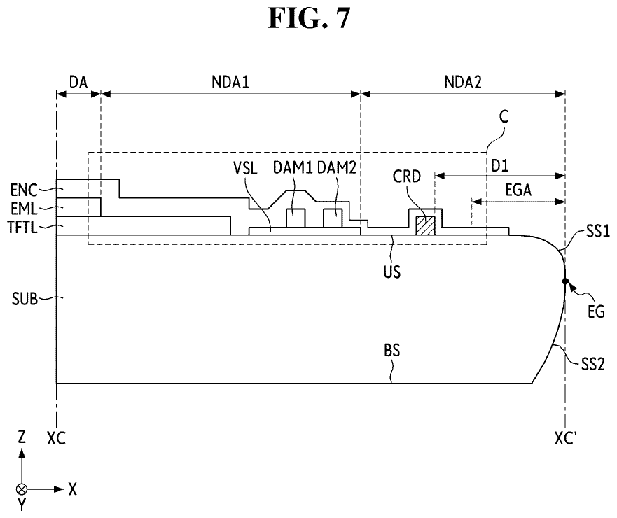

In an embodiment, a distance D1 (see FIG. 7) between the crack dam CRD and the edge EG may be about 130 μm or less, and a distance between the crack dam CRD and the edge area EGA may be about 80 μm or less. The minimum distance from the crack dam CRD, which is the outermost structure, to the edge EG of the display panel 100 may vary depending on the width of the edge area EGA and the minimum distance from the crack dam CRD to the edge area EGA.

FIG. 7 is a cross-sectional view showing an example of a display panel taken along line XC-XC′ of FIG. 6.

FIG. 7 schematically illustrates a cross-section of the display panel 100 in a case where the substrate SUB of the display panel 100 is cut by radiating a laser and then spraying an etchant during the manufacturing process of the display panel 100.

Referring to FIG. 7, the edge area EGA may be a region where processing traces are formed on a top surface US of the substrate SUB by the radiated laser, when the substrate SUB is cut by radiating the laser and then spraying an etchant. In an embodiment, a width of the edge area EGA may be less than or equal to about 50 μm, but is not limited thereto. In the display panel 100, the edge area EGA, where traces of laser processing remain, may be formed with a width of about 50 μm or less along the edge EG.

The substrate SUB of the display panel 100 may include the top surface US on which the light emitting element layer EML is disposed, a bottom surface BS on the opposite side of the top surface US, and a curved side surface SS1 and SS2 connected to the top surface US and the bottom surface BS. The substrate SUB of the display panel 100 may include the edge EG, which is an outermost protruding portion of the curved side surface SS1 and SS2, and the side surface SS1 and SS2 may include a first side surface SS1 between the edge EG and the top surface US, and a second side surface SS2 between the edge EG and the bottom surface BS.

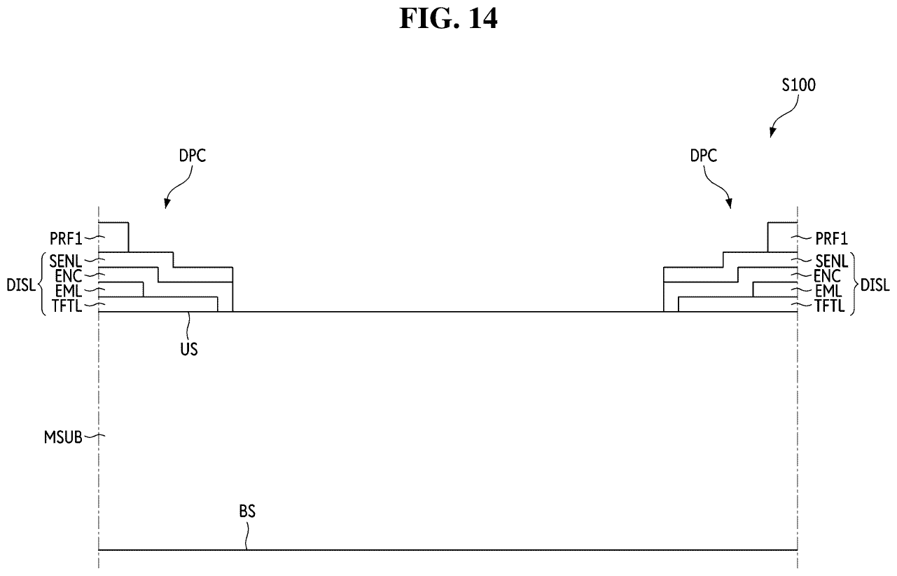

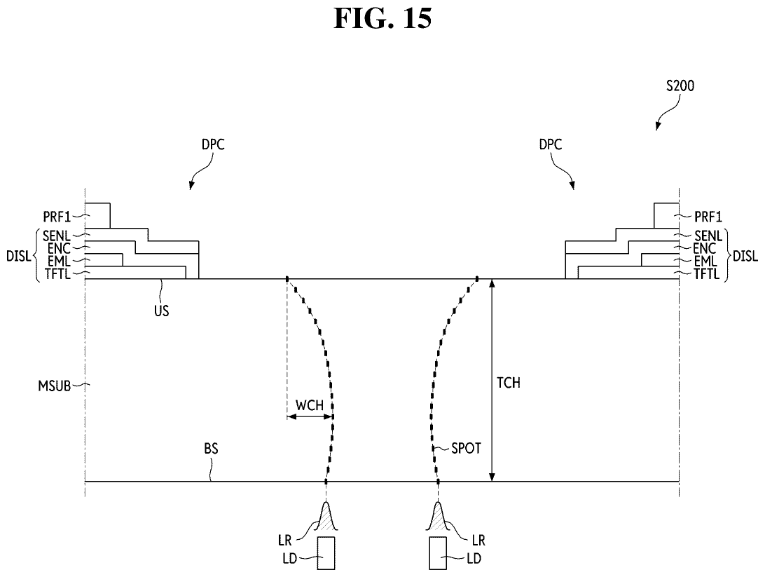

The substrate SUB may be cut from a mother substrate MSUB (see FIG. 14) through a laser irradiation and etching process in the manufacturing process of the display device 10. Here, the shape of the side surface SS1 and SS2 of the substrate SUB of the display panel 100 may be controlled by designing the position of a laser spot SPOT (see FIG. 15) that is radiated to the mother substrate MSUB (see FIG. 14). According to an embodiment, in the process of cutting the substrate SUB from the mother substrate MSUB (see FIG. 14) during the manufacturing process of the display device 10, a position where the laser spot SPOT (see FIG. 15) is radiated may have a curved shape in three-dimensional space, and the side surface SS1 and SS2 of the cut substrate SUB may also have a curved shape.

In the process of cutting the substrate SUB, the laser and etching process may be performed from one side of the mother substrate MSUB (see FIG. 14). The side surface SS1 and SS2 of the cut substrate SUB may include a side surface adjacent to one surface where the laser and etching process is performed, and a side surface adjacent to the other surface, which is opposite to the one surface, where the laser and etching process is not performed. In an embodiment, a laser may be radiated and an etching process may be performed on the bottom surface BS of the substrate SUB during the manufacturing process of the display device 10, and the side surface SS1 and SS2 of the substrate SUB may include the first side surface SS1 adjacent to the top surface US and the second side surface SS2 adjacent to the bottom surface BS. The first side surface SS1 and the second side surface SS2 may have different degrees of exposure to the laser and etching process in the cutting process of the substrate SUB, and may each have a curvature but the shapes of the first side surface SS1 and the second side surface SS2 may differ from each other.

In an embodiment, the substrate SUB of the display panel 100 may include the outermost edge EG, the first side surface SS1 between the edge EG and the top surface US, and the second side surface SS2 between the edge EG and the bottom surface BS. The first side surface SS1 and the second side surface SS2 may each have a curvature and may be formed to be curved from the ends of the top surface US and bottom surface BS to the edge EG.

The first side surface SS1 and the second side surface SS2 may each have a curvature varying depending on the design such as the position and spacing of the laser spot SPOT (see FIG. 15) radiated during the laser process. In an embodiment, the edge EG of the substrate SUB of the display panel 100 may be positioned closer to the top surface US than the bottom surface BS, rather than being positioned at the center in the thickness direction. Accordingly, the lengths of the first side surface SS1 and the second side surface SS2 may differ from each other. In an embodiment, for example, the length of the first side surface SS1 may be less than the length of the second side surface SS2, and the curvature of the first side surface SS1 may be greater than the curvature of the second side surface SS2. That is, the second side surface SS2 may have a gentler curvature than the first side surface SS1.

In an embodiment, in the substrate SUB of the display panel 100, the curvature of the second side surface SS2, which has a gentle curvature, may be in a range from about 200 μmR to 300 μmR, or from 220 μmR to 260 μmR, or about 240 μmR, but is not limited thereto. As the second side surface SS2, which is adjacent to the bottom surface BS where display elements such as the light emitting element layer EML are not disposed, has a gentler curvature than the first side surface SS1, the substrate SUB may have greater impact resistance against external impact.

If the side surface SS1 and SS2 of the substrate SUB of the display panel 100 have a vertical or inclined shape with respect to the top surface US and the bottom surface BS, the resistance to external impact may be low. In an embodiment of the display device 10, the substrate SUB of the display panel 100 may have the side surface SS1 and SS2 having a relatively gentle curvature from the top surface US and the bottom surface BS to improve resistance to external impact. The shape of the side surface SS1 and SS2 may vary depending on the conditions of the laser irradiation process and the etching process performed during the separation process of the substrate SUB in the manufacturing process of the display device 10, as described above. A more detailed description thereof will be provided later together with the manufacturing process.

The position of the edge EG may also vary depending on the design of the laser spot SPOT (see FIG. 15) radiated during the cutting process of the substrate SUB, and the process condition of the etching process performed after the laser process.

In an embodiment, the substrate SUB of the display panel 100 may be cut by radiating a laser and then spraying an etchant during the manufacturing process of the display panel 100, and the first side surface SS1 and the second side surface SS2 of the display panel 100 may be etched by the etchant. The roughness of the first side surface SS1 and the second side surface SS2 of the display panel 100 may be about 0.5 μm or less. In an embodiment where the substrate SUB of the display panel 100 is cut by radiating a laser and then spraying an etchant, the roughness of the first side surface SS1 and the second side surface SS2 of the display panel 100 may be relatively smaller than a case where the substrate SUB is cut by a cutting member and then a polishing process is performed.

As described above, since the etching process proceeds from the bottom surface BS of the substrate SUB in the cutting process of the substrate SUB, the first side surface SS1 and the second side surface SS2 of the display panel 100 may have different degrees of exposure to the etchant. Accordingly, the roughness of the first side surface SS1 and the roughness of the second side surface SS2 of the display panel 100 may differ from each other. In an embodiment, for example, the roughness of the first side surface SS1 and the roughness of the second side surface SS2 of the display panel 100 may differ from each other by about 1% to about 20%.

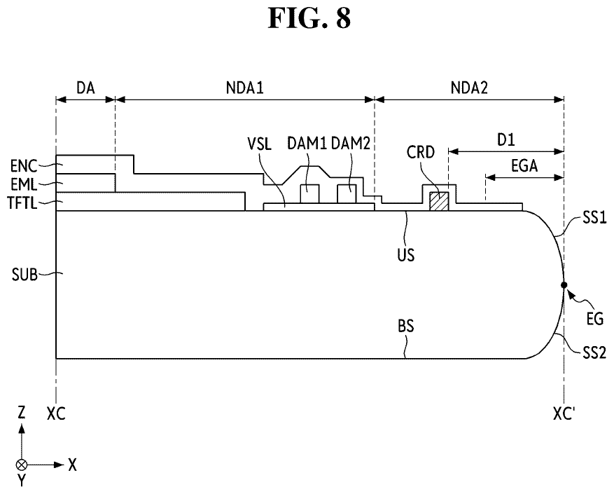

FIG. 8 is a cross-sectional view showing another example of a display panel taken along line XC-XC′ of FIG. 6.

Referring to FIG. 8, in another embodiment, the edge EG may be positioned at the midpoint of the total thickness of the substrate SUB or at a center in the third direction, and the first side surface SS1 and the second side surface SS2 may have substantially a same curvature and substantially a same length as each other. The first side surface SS1 and the second side surface SS2 may have a symmetrical shape with respect to the edge EG. As a result, the side surface SS1 and SS2 of the substrate SUB may have a shape having a uniform curvature, and resistance to external impact may be further improved.

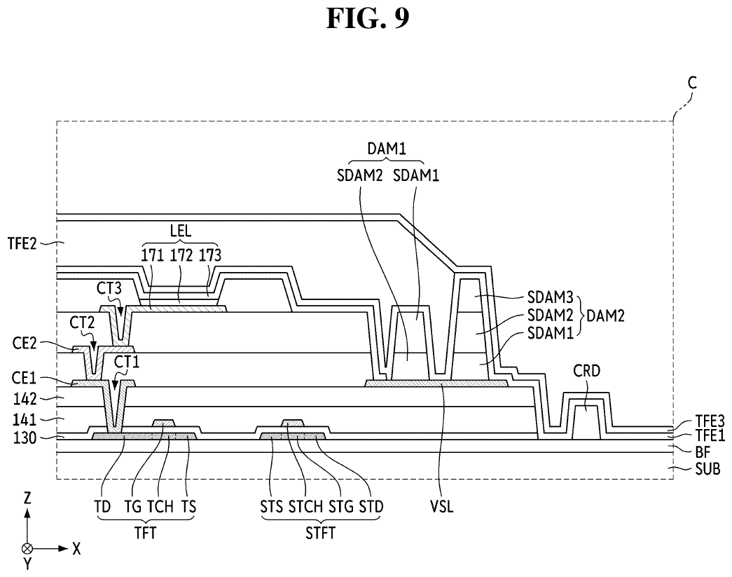

FIG. 9 is an enlarged view of area C of FIG. 7.

Referring to FIG. 9, the first power line VSL may include a same material as the first data metal layer including the first connection electrode CE1 and the data lines, and may be disposed in (or directly on) a same layer as each other. The first power line VSL may be disposed on the second interlayer insulating film 142. The first power line VSL may be formed as a single layer or multiple layers including at least one selected from molybdenum (Mo), aluminum (Al), chromium (Cr), gold (Au), titanium (Ti), nickel (Ni), neodymium (Nd), and copper (Cu) or an alloy thereof.

The first dam DAM1 and the second dam DAM2 may be disposed on the first power line VSL. The first dam DAM1 may include a first sub-dam SDAM1 and a second sub-dam SDAM2, and the second dam DAM2 may include a first sub-dam SDAM1, a second sub-dam SDAM2, and a third sub-dam SDAM3. The first sub-dam SDAM1 and the first organic film 160 may include a same material, and may be disposed in (or directly on) a same layer as each other. The second sub-dam SDAM2 and the second organic film 180 may include a same material, and may be disposed in (or directly on) a same layer as each other. The third sub-dam SDAM3 may include a same material as the bank 190 and may be disposed in (or directly on) a same layer as each other.

The height of the first dam DAM1 may be lower than the height of the second dam DAM2, but the disclosure is not limited thereto. The height of the first dam DAM1 may be substantially the same as the height of the second dam DAM2 or may be higher than the height of the second dam DAM2.

The common electrode 173 may be connected to the first power line VSL exposed without being covered by the first organic film 160, the second organic film 180, and the first dam DAM1. Accordingly, the common electrode 173 may be supplied with the first source voltage of the first power line VSL.

The first encapsulation inorganic film TFE1 may cover the first dam DAM1, the second dam DAM2, and the crack dam CRD in the non-display area NDA on the left side of the display panel 100.

The encapsulation organic film TFE2 may be disposed to cover the top surface of the first dam DAM1 without covering the top surface of the second dam DAM2. However, the disclosure is not limited thereto. The encapsulation organic film TFE2 may not cover both the top surface of the first dam DAM1 and the top surface of the second dam DAM2. The encapsulation organic film TFE2 may not overflow to the edge EG of the display panel 100 due to the first dam DAM1 and the second dam DAM2.

The second encapsulation inorganic film TFE3 may cover the first dam DAM1, the second dam DAM2, and the crack dam CRD in the non-display area NDA on the left side of the display panel 100.

An inorganic encapsulation area in which the first encapsulation inorganic film TFE1 and the second encapsulation inorganic film TFE3 are in contact with each other may be formed from the second dam DAM2 to a region adjacent to the edge EG of the display panel 100. The inorganic encapsulation area may be disposed to surround the second dam DAM2. The display panel 100 may include the encapsulation layer ENC extending to the edge EG and the crack dam CRD disposed at the outer portion, thereby ensuring reliability in a region where the inorganic film is directly disposed on the substrate SUB of the display panel 100. In an embodiment of the display panel 100 of the display device 10, the first encapsulation inorganic film TFE1 and the second encapsulation inorganic film TFE3 of the encapsulation layer ENC may extend to the edge EG of the display panel 100, and the edge area EGA may overlap the encapsulation layer ENC.

The crack dam CRD may include a same material as the first organic film 160, but may be disposed on the buffer film BF. However, it is not limited thereto, and the crack dam CRD may be disposed on the second interlayer insulating film 142, similarly to the first organic film 160. The crack dam CRD may include or be formed of an organic film such as acryl resin, epoxy resin, phenolic resin, polyamide resin, polyimide resin and the like. In an embodiment, the width of the crack dam CRD may be about 30 μm or less.

Although FIG. 9 illustrates an embodiment where the crack dam CRD includes one organic film, the disclosure is not limited thereto. In an embodiment, for example, the crack dam CRD may further include another organic film including a same material as the second organic film 180. Alternatively, the crack dam CRD may further include another organic film including the same material as the bank 190. Alternatively, the crack dam CRD may further include another organic film including the same material as the spacer 191.

In addition, in FIG. 9, a scan thin film transistor STFT of the scan driving circuit unit SDC is shown as an example. Since the scan thin film transistor STFT is substantially the same as the thin film transistor TFT described in conjunction with FIG. 5, any repetitive detailed description of the scan thin film transistor STFT will be omitted.

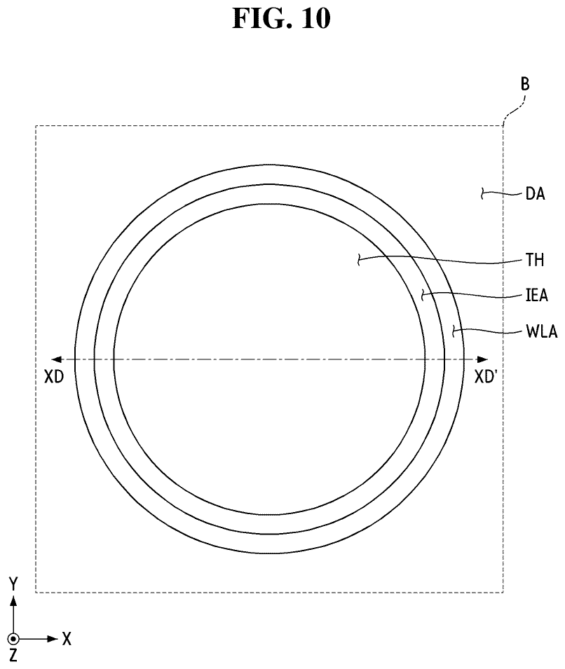

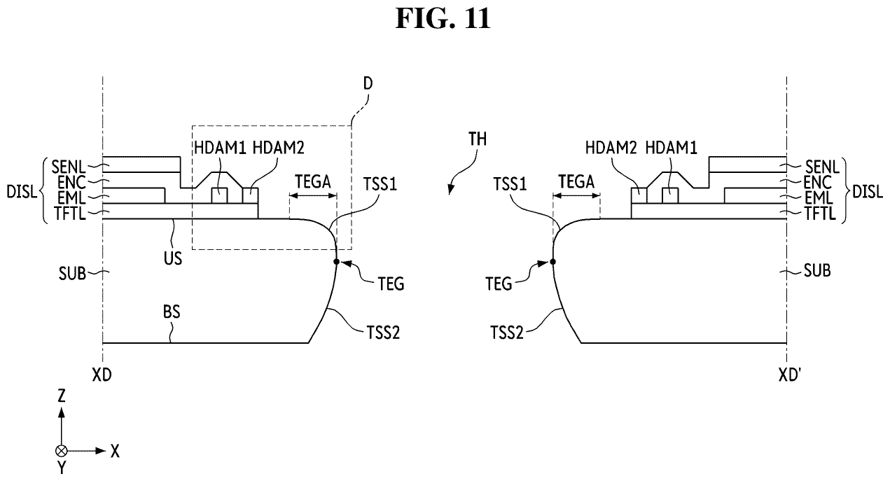

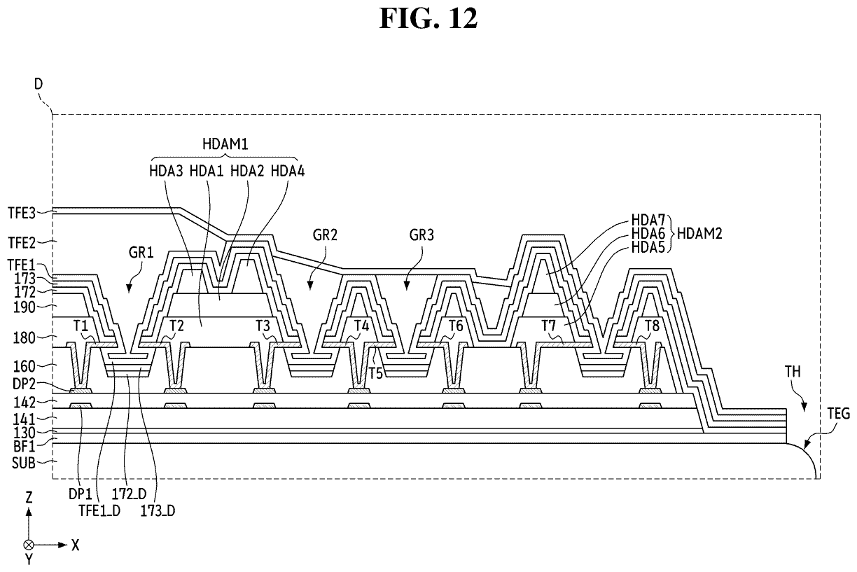

FIG. 10 is an enlarged view of area B of FIG. 2. FIG. 11 is a cross-sectional view taken along line XD-XD′ of FIG. 10. FIG. 12 is an enlarged view of area D of FIG. 11.

Referring to FIGS. 10 to 12, the display panel 100 according to an embodiment includes an inorganic encapsulation area IEA surrounding the through hole TH and a wiring area WLA surrounding the inorganic encapsulation area IEA.

The first encapsulation inorganic film TFE1 and the second encapsulation inorganic film TFE3 of the encapsulation layer ENC may be in contact with each other, and the inorganic encapsulation area IEA may be a layer for preventing oxygen or moisture from permeating into the light emitting element layer EML of the display layer DISL due to the through hole TH.

The inorganic encapsulation area IEA may include at least one dam, at least one tip, and at least one groove. In an embodiment, for example, as illustrated in FIG. 12, the inorganic encapsulation area IEA may include a first hole dam HDAM1, a second hole dam HDAM2, first to eighth tips T1 to T8, and first to third grooves GR1 to GR3.

The first tip T1 and the second tip T2 may be disposed closer to the wiring area WLA than the first hole dam HDAM1. The first tip T1 may be disposed closer to the wiring area WLA than the second tip T2. The second tip T2 may be disposed between the first tip T1 and the first hole dam HDAM1.

The third tip T3, the fourth tip T4, the fifth tip T5, and the sixth tip T6 may be disposed between the first hole dam HDAM1 and the second hole dam HDAM2. At least a part of the third tip T3 may overlap the first hole dam HDAM1 in the third direction (Z-axis direction).

The seventh tip T7 and the eighth tip T8 may be disposed closer to the through hole TH than the second hole dam HDAM2. At least a part of the seventh tip T7 may overlap the second hole dam HDAM2 in the third direction (Z-axis direction). A distance between the eighth tip T8 and the through hole TH may be about 50 μm, but is not limited thereto.

The first groove GR1 may be defined between the first tip T1 and the second tip T2. The second groove GR2 may be defined between the third tip T3 and the fourth tip T4. The third groove GR3 may be defined between the fifth tip T5 and the sixth tip T6.

The wiring area WLA may be an area in which bypass lines due to the through hole TH are disposed. Some of the bypass lines may be connected to data lines, and some others of the bypass lines may be connected to a second power line to which a second source voltage higher than the first source voltage is applied. Yet some others of the bypass lines may be connected to the scan lines. The wiring area WLA may be surrounded by the display area DA.

FIG. 11 schematically illustrates a cross-section of an edge TEG of the through hole TH in a case where the substrate SUB of the display panel 100 is cut by radiating a laser and then spraying an etchant during the manufacturing process of the display panel 100.

As shown in FIG. 11, a through hole edge area TEGA may be a region where processing traces are formed on the top surface US of the substrate SUB by the radiated laser, when the substrate SUB is cut by radiating the laser and then spraying an etchant. In an embodiment, a width of the through hole edge area TEGA may be less than or equal to about 50 μm, but is not limited thereto. In the display panel 100, the edge area EGA, where traces of laser processing remain, may be formed with a width of about 50 μm or less along the edge TEG of the through hole TH.

The substrate SUB of the display panel 100 may include a curved through hole side surface TSS1 and TSS2 connected to the top surface US and the bottom surface BS. The substrate SUB of the display panel 100 may include an edge TEG of the through hole TH, which is an outermost protruding portion of the curved through hole side surface TSS1 and TSS2, and the through hole side surface TSS1 and TSS2 may include a first through hole side surface TSS1 between the edge TEG of the through hole TH and the top surface US, and a second through hole side surface TSS2 between the edge TEG of the through hole TH and the bottom surface BS.

Similarly to the side surface SS1 and SS2 (see FIG. 7) of the substrate SUB of the display panel 100, the shape of the through hole side surface TSS1 and TSS2 may also be controlled according to the design of the position of the laser spot SPOT (see FIG. 15) radiated to the mother substrate MSUB (see FIG. 14) in the manufacturing process of the display device 10. According to an embodiment, in the process of cutting the substrate SUB from the mother substrate MSUB (see FIG. 14) during the manufacturing process of the display device 10, a position where the laser spot SPOT (see FIG. 15) is radiated may have a curved shape in three-dimensional space, and the through hole side surface TSS1 and TSS2 of the cut substrate SUB may also have a curved shape.

In the process of cutting the substrate SUB, the laser and etching process may be performed from one side of the mother substrate MSUB (see FIG. 14). The through hole side surface TSS1 and TSS2 of the cut substrate SUB may include a side surface adjacent to one surface where the laser and etching process is performed, and a side surface adjacent to the other surface, which is opposite to the one surface, where the laser and etching process is not performed. In an embodiment, a laser may be radiated and an etching process may be performed on the bottom surface BS of the substrate SUB during the manufacturing process of the display device 10, and the through hole side surface TSS1 and TSS2 of the substrate SUB may include the first through hole side surface TSS1 adjacent to the top surface US and the second through hole side surface TSS2 adjacent to the bottom surface BS. The first through hole side surface TSS1 and the second through hole side surface TSS2 may have different degrees of exposure to the laser and etching process in the cutting process of the substrate SUB, and may each have a curvature but their shapes may differ from each other.

In an embodiment, the substrate SUB of the display panel 100 may include the edge TEG of the through hole TH, the first through hole side surface TSS1 between the edge TEG of the through hole TH and the top surface US, and the second through hole side surface TSS2 between the edge TEG of the through hole TH and the bottom surface BS. The first through hole side surface TSS1 and the second through hole side surface TSS2 may each have a curvature and may be formed to be curved from the ends of the top surface US and the bottom surface BS to the edge TEG of the through hole TH.

The first through hole side surface TSS1 and the second through hole side surface TSS2 may each have a curvature varying depending on the design such as the position and spacing of the laser spot SPOT (see FIG. 15) radiated during the laser process. In an embodiment, the edge TEG of the through hole TH of the substrate SUB of the display panel 100 may be positioned closer to the top surface US than the bottom surface BS, rather than being positioned at the center in the thickness direction. Accordingly, the lengths of the first through hole side surface TSS1 and the second through hole side surface TSS2 may differ from each other. In an embodiment, for example, the length of the first through hole side surface TSS1 may be less than the length of the second through hole side surface TSS2, and the curvature of the first through hole side surface TSS1 may be greater than the curvature of the second through hole side surface TSS2. That is, the second through hole side surface TSS2 may have a gentler curvature than the first through hole side surface TSS1.

In an embodiment, in the substrate SUB of the display panel 100, the curvature of the second through hole side surface TSS2, which has a gentle curvature, may range from about 200 μmR to 300 μmR, or from 220 μmR to 260 μmR, or around 240 μmR, but is not limited thereto. As the second through hole side surface TSS2, which is adjacent to the bottom surface BS where display elements such as the light emitting element layer EML are not disposed, has a gentler curvature than the first through hole side surface TSS1, the substrate SUB may have greater impact resistance against external impact.

If the through hole side surface TSS1 and TSS2 of the substrate SUB of the display panel 100 have a vertical or inclined shape with respect to the top surface US and the bottom surface BS, the resistance to external impact may be low. In an embodiment of the display device 10, the substrate SUB of the display panel 100 may have the through hole side surface TSS1 and TSS2 having a relatively gentle curvature from the top surface US and the bottom surface BS, to improve resistance to external impact. The shape of the through hole side surface TSS1 and TSS2 may vary depending on the conditions of the laser irradiation process and the etching process performed during the separation process of the substrate SUB in the manufacturing process of the display device 10, as described above. A more detailed description thereof will be provided later together with the manufacturing process.

The position of the edge TEG of the through hole may also vary depending on the design of the laser spot SPOT (see FIG. 15) radiated during the cutting process of the substrate SUB, and the process condition of the etching process performed after the laser process.

In an embodiment, the substrate SUB of the display panel 100 may be cut by radiating a laser and then spraying an etchant during the manufacturing process of the display panel 100, and the first through hole side surface TSS1 and the second through hole side surface TSS2 of the display panel 100 may be etched by the etchant. The roughness of the first through hole side surface TSS1 and the second through hole side surface TSS2 of the display panel 100 may be about 0.5 μm or less. In an embodiment where the substrate SUB of the display panel 100 is cut by radiating a laser and then spraying an etchant, the roughness of the first through hole side surface TSS1 and the second through hole side surface TSS2 of the display panel 100 may be relatively smaller than a case where the substrate SUB is cut by a cutting member and then a polishing process is performed.

In an embodiment, as described above, since the etching process proceeds from the bottom surface BS of the substrate SUB in the cutting process of the substrate SUB, the first through hole side surface TSS1 and the second through hole side surface TSS2 of the display panel 100 may have different degrees of exposure to the etchant. Accordingly, the roughness of the first through hole side surface TSS1 and the roughness of the second through hole side surface TSS2 of the display panel 100 may differ from each other. In an embodiment, for example, the roughness of the first through hole side surface TSS1 and the roughness of the second through hole side surface TSS2 of the display panel 100 may differ from each other by about 1% to about 20%.

In another embodiment, although not shown in the drawing, similarly to the side surface SS1 and SS2 (see FIG. 8) of the substrate SUB of the display panel 100, the edge TEG of the through hole TH may be positioned at the midpoint of the total thickness of the substrate SUB, and the first through hole side surface TSS1 and the second through hole side surface TSS2 may have the same curvature and the same length. The first through hole side surface TSS1 and the second through hole side surface TSS2 may have a symmetrical shape with respect to the edge TEG of the through hole TH. As a result, the through hole side surface TSS1 and TSS2 of the substrate SUB may have a shape having a uniform curvature, and resistance to external impact may be further improved.

In an embodiment, as illustrated in FIGS. 5 and 12, a first dummy pattern DP1 may include a same material as the second gate metal layer including the second capacitor electrode CAE2 of the capacitor Cst and may be disposed in (or directly on) a same layer. In an embodiment, for example, the first dummy pattern DP1 may be disposed on the first interlayer insulating film 141. The first dummy pattern DP1 may be formed as or defined by a single layer or multiple layers including at least one selected from molybdenum (Mo), aluminum (Al), chromium (Cr), gold (Au), titanium (Ti), nickel (Ni), neodymium (Nd) and copper (Cu) or an alloy thereof.

A second dummy pattern DP2 may include a same material as the first data metal layer including the first connection electrode CE1 and the data lines and may be disposed in (or directly on) a same layer. In an embodiment, for example, the second dummy pattern DP2 may be disposed on the second interlayer insulating film 142. The second dummy pattern DP2 may be formed as a single layer or multiple layers including at least one selected from molybdenum (Mo), aluminum (Al), chromium (Cr), gold (Au), titanium (Ti), nickel (Ni), neodymium (Nd) and copper (Cu) or an alloy thereof.

The second dummy pattern DP2 may overlap the first dummy pattern DP1 in the third direction (Z-axis direction).

The first to eighth tips T1 to T8 may include the same material as the second data metal layer including the second connection electrode CE2 and may be disposed on the same layer. In an embodiment, for example, the first to eighth tips T1 to T8 may be disposed on the first organic film 160. The first to eighth tips T1 to T8 may be formed as a single layer or multiple layers including at least one selected from molybdenum (Mo), aluminum (Al), chromium (Cr), gold (Au), titanium (Ti), nickel (Ni), neodymium (Nd) and copper (Cu) or an alloy thereof.

Each of the first to eighth tips T1 to T8 may be connected to the second dummy pattern DP2 through a contact hole defined through the first organic film 160. Each of the first to eighth tips T1 to T8 may include an caves structure in which the top surface and the bottom surface are exposed without being covered by the first organic film 160, the second organic film 180, the first hole dam HDAM1, and the second hole dam HDAM2. The fourth tip T4 and the fifth tip T5 may be integrally formed as a single unitary indivisible part. Each of the first to eighth tips T1 to T8 may be a protruding pattern or a trench pattern for forming a groove (or trench). The eighth tip T8 may be an outermost structure adjacent to the edge TEG of the through hole TH. In FIG. 12, the eighth tip T8 is illustrated as an outermost structure adjacent to the edge TEG of the through hole TH, but the disclosure is not limited thereto. In an embodiment, for example, where the seventh tip T7 and the eighth tip T8 are omitted, the outermost structure adjacent to the edge TEG of the through hole TH may be the second hole dam HDAM2 for preventing overflow of the encapsulation organic film TFE2 of the encapsulation layer ENC. In another embodiment, where the seventh tip T7 and the eighth tip T8 are omitted, the outermost structure adjacent to the edge TEG of the through hole TH may be a groove for cutting off the light emitting layer 172 and the common electrode 173.

A distance from the eighth tip T8 to the edge TEG of the through hole TH may be about 300 μm, but is not limited thereto. The through hole edge area TEGA may be disposed between the eighth tip T8 and the edge TEG of the through hole TH.

The first groove GR1 may be formed between the first tip T1 and the second tip T2, the second groove GR2 may be formed between the third tip T3 and the fourth tip T4, and the third groove GR3 may be formed between the fifth tip T5 and the sixth tip T6. The first groove GR1 may have an caves structure formed by the first tip T1 and the second tip T2, the second groove GR2 may have an caves structure formed by the third tip T3 and the fourth tip T4, and the third groove GR3 may have an caves structure formed by the fifth tip T5 and the sixth tip T6.

In an embodiment, the light emitting layer 172 is deposited by evaporation and the common electrode 173 is deposited by sputtering, such that the light emitting layer 172 and the common electrode 173 may be disposed to be broken at each of the first to third grooves GR1, GR2, and GR3 because the step coverage is low. In such an embodiment, the first encapsulation inorganic film TFE1 and the third encapsulation inorganic film TFE3 may be deposited by chemical vapor deposition, atomic layer deposition, or the like, and thus may be formed to be continuous without being broken in each of the first to third grooves GR1, GR2, and GR3 because the step coverage is high. Step coverage refers to the ratio of the degree of thin film coated on an inclined portion to the degree of thin film coated on a flat portion. The light emitting layer 172, a broken light emitting layer remnant 172_D, the common electrode 173, and a broken common electrode remnant 173_D may be disposed in the first to third grooves GR1, GR2, and GR3, respectively.

The first hole dam HDAM1 may include first to fourth sub-dams HDA1, HDA2, HDA3, and HDA4. The first sub-dam HDA1 may be disposed on the first organic film 160 and may include the same material as the second organic film 180. The first sub-dam HDA1 may be disposed on the second tip T2 and the third tip T3. The second sub-dam HDA2 may be disposed on the first sub-dam HDA1 and may include the same material as the bank 190. The third sub-dam HDA3 and the fourth sub-dam HDA4 may be disposed on the second sub-dam HDA2 and may include the same material as the spacer 191, but are not limited thereto. The fourth sub-dam HDA4 may be disposed closer to the through hole TH than the third sub-dam HDA3. The thickness of the fourth sub-dam HDA4 may be greater than the thickness of the third sub-dam HDA3.

The second hole dam HDAM2 may include fifth to seventh sub-dams HDA5, HDA6, and HDA7. The fifth sub-dam HDA5 may be disposed on the first organic film 160 and may include a same material as the second organic film 180. The fifth sub-dam HDA5 may be disposed on the seventh tip T7. The sixth sub-dam HDA6 may be disposed on the fifth sub-dam HDA5 and may include a same material as the bank 190. The seventh sub-dam HDA7 may be disposed on the sixth sub-dam HDA6 and may include the same material as the spacer 191, but is not limited thereto.

The overflow of the encapsulation organic film TFE2 into the through hole TH may be effectively prevented by the first hole dam HDAM1 and the second hole dam HDAM2.

The light emitting layer remnant 172_D, the common electrode remnant 173_D, the first encapsulation inorganic film TFE1, and the second encapsulation inorganic film TFE3 may extend to the edge TEG of the through hole TH. The end of the light emitting layer remnant 172_D, the end of the common electrode remnant 173_D, the end of the first encapsulation inorganic film TFE1, or the end of the second encapsulation inorganic film TFE3 may coincide with the edge TEG of the through hole TH.

In an embodiment, as illustrated in FIG. 12, since the light emitting layer 172 and the common electrode 173 are broken in the first to third grooves GR1, GR2, and GR3 formed by the first to eighth tips T1 to T8, respectively, it is possible to effectively prevent the light emitting layer 172 and the common electrode 173 exposed through the through hole TH from being a path through which oxygen, moisture, or the like permeates.

Hereinafter, a method for manufacturing a display device according to an embodiment will be described.

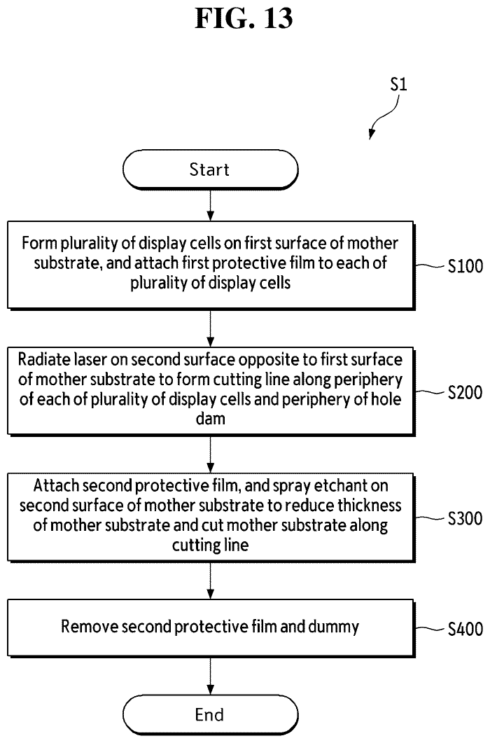

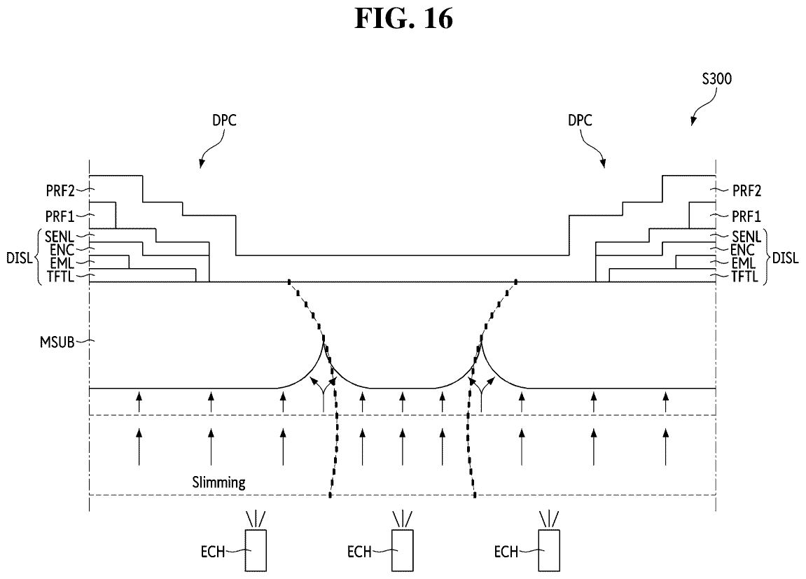

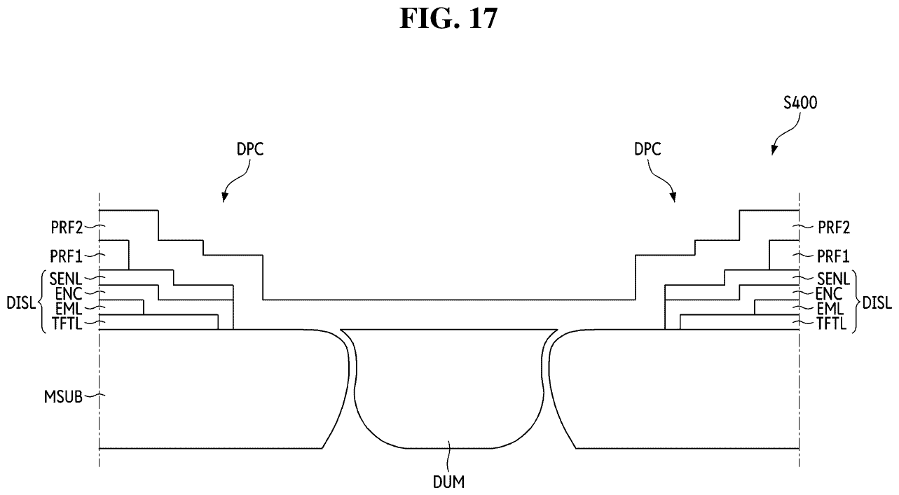

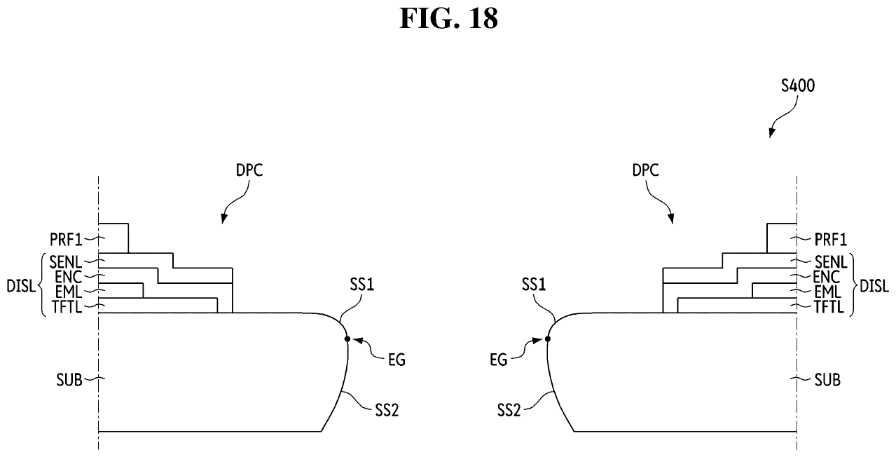

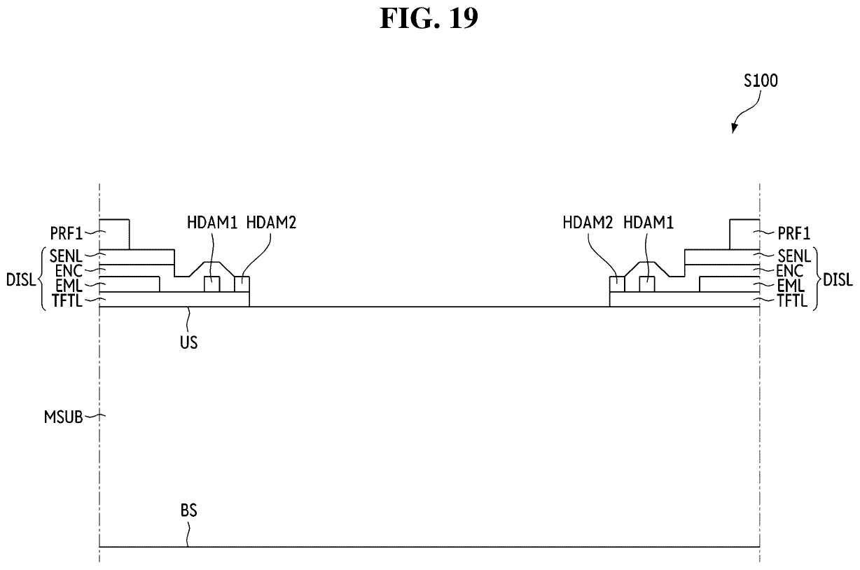

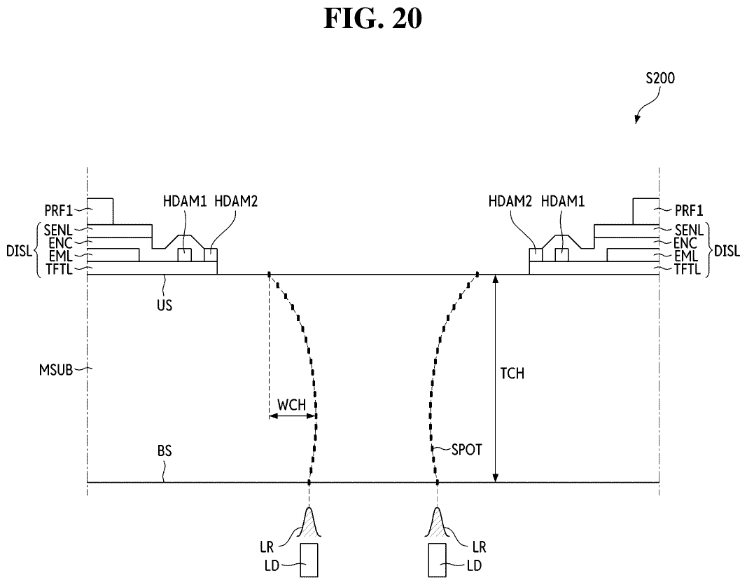

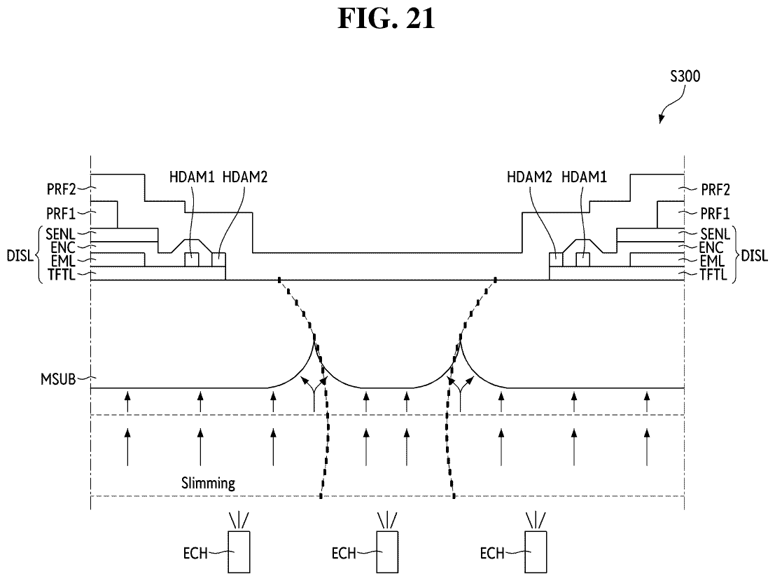

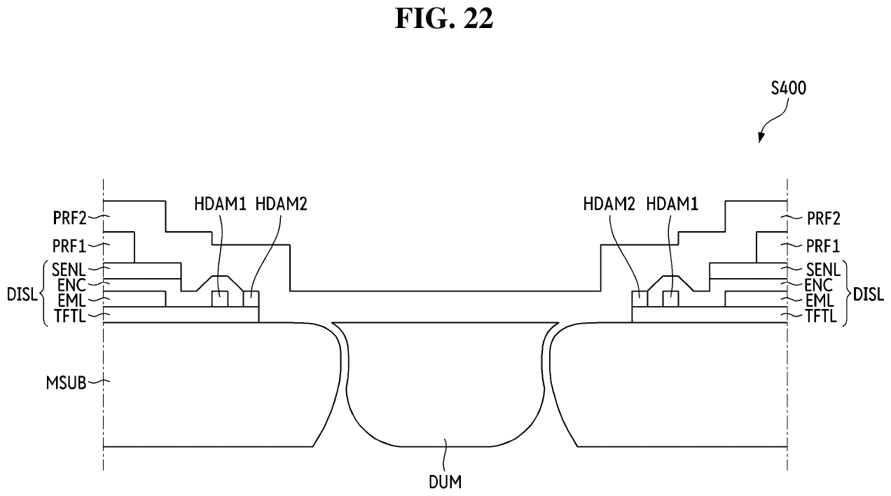

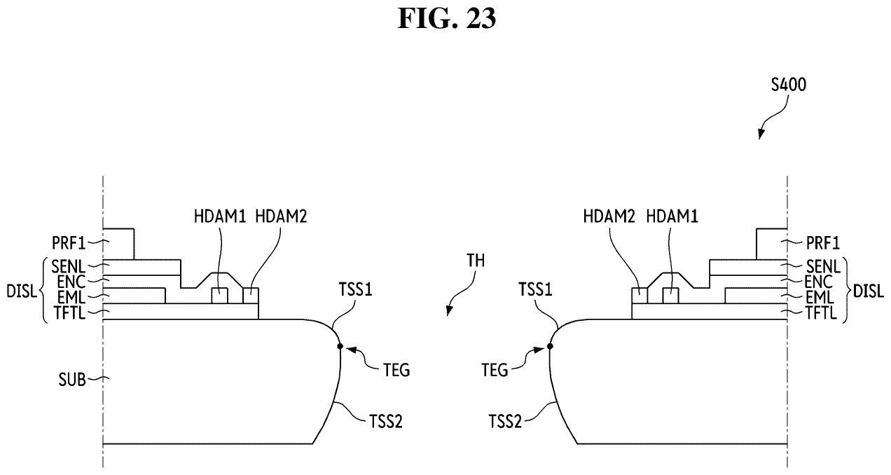

FIG. 13 is a flowchart showing a method for manufacturing a display device according to an embodiment. FIG. 14 is a cross-sectional view showing display cells and a region interposed therebetween in process S100 of FIG. 13. FIG. 15 is a cross-sectional view showing display cells and a region interposed therebetween in process S200 of FIG. 13. FIG. 16 is a cross-sectional view showing display cells and a region interposed therebetween in process S300 of FIG. 13. FIGS. 17 and 18 are cross-sectional views showing display cells and a region interposed therebetween in process S400 of FIG. 13. FIG. 19 is a cross-sectional view showing hole dams and a region interposed therebetween in process S100 of FIG. 13. FIG. 20 is a cross-sectional view showing hole dams and a region interposed therebetween in process S200 of FIG. 13. FIG. 21 is a cross-sectional view showing hole dams and a region interposed therebetween in process S300 of FIG. 13. FIGS. 22 and 23 are cross-sectional views showing hole dams and a region interposed therebetween in process S400 of FIG. 13.

Referring to FIGS. 13 to 23, a display device manufacturing method S1 according to an embodiment may include forming a plurality of display cells on a first surface of the mother substrate, and attaching a first protective film to each of the plurality of display cells (process S100); radiating a laser on a second surface opposite to the first surface of the mother substrate to form a cutting line along the periphery of each of the plurality of display cells and the periphery of the hole dam (process S200); attaching a second protective film, and spraying an etchant on the second surface of the mother substrate to reduce the thickness of the mother substrate and cut the mother substrate along the cutting line (process S300); and removing the second protective film and a dummy (process S400).

The display device 10 may be formed by a process of separating the plurality of substrates SUB, each having one display cell DPC formed thereon, from the mother substrate MSUB on which a plurality of display cells DPC are formed. The process of separating the plurality of substrates SUB from the mother substrate MSUB may include a process of radiating a laser and a process of etching the mother substrate MSUB to separate the substrates SUB. The display device 10 may be manufactured by performing a laser process, and accordingly, the substrate SUB may minimize the area of the outer portion where the display cell DPC is not disposed. According to an embodiment, in the manufacturing process of the display device 10, the shape of the side surface of the substrate SUB cut from the mother substrate MSUB may be formed to be curved by designing a position where the laser spot SPOT is formed in the process of radiating a laser LR. Accordingly, in an embodiment of the display device 10, the substrate SUB of the display panel 100 may have high resistance to external impact.

First, as shown in FIGS. 14 and 19, in process S100, the plurality of display cells DPC are formed on the first surface of the mother substrate MSUB, a plurality of first protective films PRF1 are attached onto the plurality of display cells DPC, and the plurality of display cells DPC are inspected.

The display layer DISL of each of the plurality of display cells DPC is formed on the first surface (e.g., the top surface US) of the mother substrate MSUB. The display layer DISL includes the thin film transistor layer TFTL, the light emitting element layer EML, the encapsulation layer ENC, and the sensor electrode layer SENL. The structure of the display layer DISL is the same as those described above, and any repetitive detailed description thereof will be omitted.

Subsequently, a first protective film layer is attached to cover the plurality of display cells DPC and the mother substrate MSUB disposed between the plurality of display cells DPC. Then, by removing a portion of the first protective film layer disposed on the mother substrate MSUB, the plurality of first protective films PRF1 may be disposed on the plurality of display cells DPC, respectively. A part of the first protective film layer may be removed, and the remaining portions thereof may define the plurality of first protective films PRF1. The plurality of first protective films PRF1 may be disposed on the plurality of display cells DPC, respectively. The plurality of first protective films PRF1 may be disposed in a one-to-one correspondence with the plurality of display cells DPC.

Each of the plurality of first protective films PRF1 may be a buffer film for protecting the plurality of display cells DPC from external impact. The plurality of first protective films PRF1 may include or be made of a transparent material.

Then, the plurality of display cells DPC are inspected using an inspection device. After connecting a probe to a plurality of test pads provided on each of the plurality of display cells DPC, a lighting test of each of the plurality of display cells DPC may be performed.

In an embodiment where the lighting test is performed after separating the plurality of display cells DPC from the mother substrate MSUB by the cutting process, an additional process for removing the plurality of test pads may be performed after completing the lighting test. In an embodiment, where the lighting test is performed on the mother substrate MSUB before separating the plurality of display cells DPC from the mother substrate MSUB, the plurality of test pads are removed when the plurality of display cells DPC may be separated from the mother substrate MSUB through laser irradiation and etching later. Accordingly, when the lighting test is performed on the mother substrate MSUB, no additional process for removing the plurality of test pads is performed.

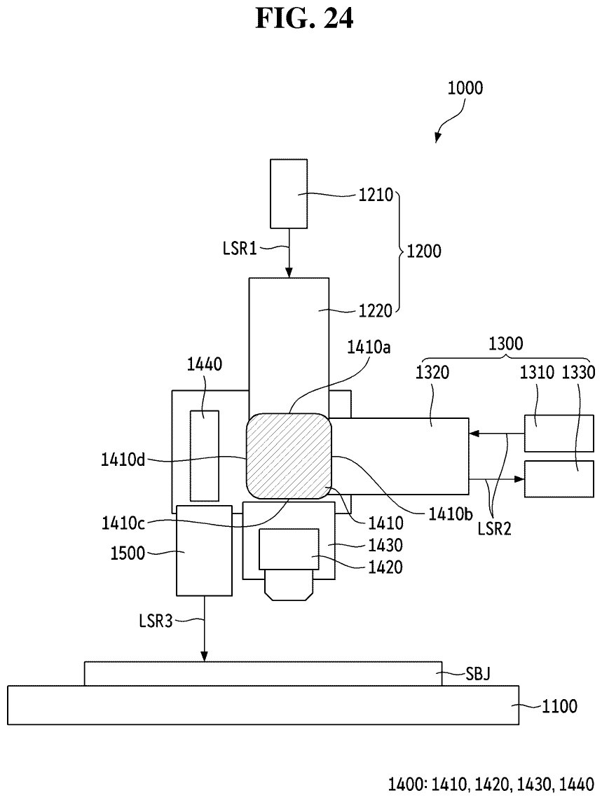

Next, as shown in FIGS. 15 and 20, in process S200, the laser LR is radiated on the second surface (e.g., the bottom surface BS) opposite to the first surface of the mother substrate MSUB to form the laser spots SPOT along the edges of the plurality of display cells DPC. The laser LR may be generated by a laser device LD. A description of the laser device LD will be provided later with reference to FIG. 24 and the like.

By radiating the laser LR to form the plurality of laser spots SPOT along the edges (between the adjacent display cells DPC) of the plurality of display cells DPC, a cutting line may be sketched or marked. The cutting line may be formed along the edges of the plurality of display cells DPC.

A variety of lasers may be used as the laser LR for sketching the cutting line. According to an embodiment, the laser LR may be a Bessel beam of the infrared range having a wavelength of about 1030 nm. The laser LR may have a repetition frequency in the range of about 10 kHz to about 1000 kHz, a pulse duration in the range of about 300 femtoseconds (fs) to about 10 picoseconds (ps), and a pulse energy in the range of about 10 microjoules (μJ) to about 500 μJ. Here, the pulse energy may be about 10 μJ or less of processing energy per laser spot SPOT. When the laser LR having the aforementioned specifications is radiated to the mother substrate MSUB, the length of the laser spot SPOT in the thickness direction of the mother substrate MSUB may be in a range from about 20 μm to about 25 μm.

According to an embodiment, the laser LR is radiated on the second surface of the mother substrate MSUB, and the laser LR may form the plurality of laser spots SPOT in the three-dimensional space of the mother substrate MSUB. The plurality of laser spots SPOT may be formed to be spaced apart from each other in the three-dimensional space. The laser LR may be radiated to the mother substrate MSUB through an optical device such as a diffractive optical element (DOE) or a spatial laser modulator (SLM), and the laser LR may simultaneously form the plurality of laser spots SPOT in the three-dimensional space of the mother substrate MSUB.

The plurality of laser spots SPOT may be formed to have a specific trajectory in the three-dimensional space of the mother substrate MSUB. The adjacent laser spots SPOT may be spaced apart from each other at regular (or irregular) intervals in the three-dimensional space, and the plurality of consecutive laser spots SPOT may be formed along a regular (or irregular) trajectory. In an etching process performed after the irradiation process of the laser LR, the etchant may permeate the laser spots SPOT and etch the mother substrate MSUB, and the mother substrate MSUB may be cut along the trajectory of the laser spots SPOT.

The shapes of the side surface SS1 and SS2 and the through hole side surface TSS1 and TSS2 of the substrate SUB cut from the mother substrate MSUB may vary in correspondence with the trajectory along which the laser spots SPOT have been formed. In the method for manufacturing the display device 10 according to an embodiment, the plurality of laser spots SPOT formed in the process of radiating the laser LR to the mother substrate MSUB may have a trajectory with a curvature in three-dimensional space, and the cut substrate SUB may have the curved side surface SS1 and SS2 and the curved through hole side surface TSS1 and TSS2.

Next, as shown in FIGS. 16 and 21, in process S300, a second protective film PRF2 may be attached onto the plurality of first protective films PRF1, and an etchant may be sprayed onto the second surface of the mother substrate MSUB without using a separate mask to etch the mother substrate MSUB.

The second protective film PRF2 may be attached to the plurality of first protective films PRF1 and the exposed mother substrate MSUB that is not covered by the plurality of first protective films PRF1. The second protective film PRF2 may cover a region where the laser spots SPOT have been formed. The second protective film PRF2 may be an acid-resistant film for protecting the plurality of display cells DPC from the etchant in an etching process of the mother substrate MSUB to be performed in the next process.

The mother substrate MSUB may be etched by spraying an etchant onto the second surface without using a separate mask. In the etching process using the etchant, the thickness of the mother substrate MSUB may be reduced and the mother substrate MSUB may be cut along the plurality of laser spots SPOT.

The thickness of the mother substrate MSUB may be reduced when spraying an etchant onto the second surface of the mother substrate MSUB. Since the mother substrate MSUB is etched without a separate mask, isotropic etching may be performed in which all regions of the second surface of the mother substrate MSUB, including the region where the laser spots SPOT have been formed, are uniformly etched.

In such an embodiment, as the thickness of the mother substrate MSUB is reduced by the etchant, when the etchant permeates the plurality of laser spots SPOT formed by the laser LR, a difference in the etching rate may occur between a region where the laser spots SPOT have been formed and a region where the laser spots SPOT have not been formed, due to the plurality of laser spots SPOT.

In the mother substrate MSUB, as the laser spots SPOT are formed in a region irradiated with the laser LR, the surface area of that region may increase compared to a region that is not irradiated with the laser LR. As the region irradiated with the laser LR has a larger surface area than other regions, an area in contact with the etchant may increase, thereby being etched with a faster etching rate. Additionally, the material properties of the mother substrate MSUB may change in the region irradiated with the laser LR. A portion of the mother substrate MSUB irradiated with the laser LR may have bonds with higher reactivity to the etchant than other portions, thereby being etched with a faster etching rate.

Therefore, the mother substrate MSUB may be subjected to anisotropic etching in which the etching rate in the region where the laser spots SPOT have been formed is faster than the etching rate in the region where the laser spots SPOT have not been formed. As a result, in the substrate SUB separated from the mother substrate MSUB, the side surface SS1 and SS2 and the through hole side surface TSS1 and TSS2 may have a curved shape similar to the laser spots SPOT, but may be further etched than the region where the laser spots SPOT have been formed. In an embodiment, the curvature of the trajectory of the laser spots SPOT formed on the mother substrate MSUB during the manufacturing process of the display device 10 may differ from the curvature of the side surface SS1 and SS2 and the through hole side surface TSS1 and TSS2 of the substrate SUB in the display panel 100 of the display device 10. This is because when the mother substrate MSUB is etched along the laser spots SPOT, the curvature of the curved surface changes due to the difference in etching rate.

Additionally, the etching process may be performed on the second surface or the bottom surface, which is a surface irradiated with the laser LR, of the mother substrate MSUB. Accordingly, in the mother substrate MSUB, there may be a difference in etching rate between the region where the laser spots SPOT have been formed and the region where the laser spots SPOT have not been formed, but there may also be a difference in etching rate between the second surface or the bottom surface of the mother substrate MSUB, and the first surface or the top surface of the mother substrate MSUB. In the mother substrate MSUB, the etching rate of the second surface may be faster than the etching rate of the first surface, and more portions may be etched along the laser spots SPOT.

That is, in the substrate SUB cut from the mother substrate MSUB, a difference in curvature due to an etching rate difference, and a difference in the glass pore size of the surface may occur between the first side surface SS1 (or the first through hole side surface TSS1) adjacent to the top surface US and the second side surface SS2 (or the second through hole side surface TSS2) adjacent to the bottom surface BS. In an embodiment, for example, as the etchant permeates from the second surface, the second side surface SS2 (or the second through hole side surface TSS2) adjacent to the bottom surface BS of the substrate SUB, which is the second surface of the mother substrate MSUB, may have a gentler curvature than the first side surface SS1 (or the first through hole side surface TSS1) adjacent to the top surface US of the substrate SUB, which is the first surface of the mother substrate MSUB. Additionally, the size of the glass pore formed on the surface of the second side surface SS2 (the second through hole side surface TSS2) may be smaller than the size of the glass pore formed on the surface of the first side surface SS1 (the first through hole side surface TSS1). A description thereof is the same as that provided above.

Since the first surface of the mother substrate MSUB is not permeated by the etchant due to the second protective film but the second surface of the mother substrate MSUB is etched by the etchant, the first surface and the second surface of the mother substrate MSUB may have differences in roughness, hardness, light transmittance, light reflectivity, local density, surface chemical structure, or the like. In an embodiment, for example, a dimple may occur due to the etchant in the second surface of the mother substrate MSUB.

Next, as shown in FIGS. 17, 18, 22, and 23, in process S400, the second protective film PRF2 may be detached after the etching process is completed.

Remaining dummy DUM pieces from the cutting of the mother substrate MSUB between the display cells DPC and from the formation of the through hole TH may be removed together with the second protective film PRF2. However, the disclosure is not limited thereto, and the dummy DUM pieces may be removed separately from the second protective film PRF2.

Hereinafter, an embodiment of an apparatus for manufacturing a display device used in a laser cutting process will be described.

FIG. 24 is a cross-sectional view showing an apparatus for manufacturing a display device according to an embodiment.

Referring to FIG. 24, a display device manufacturing apparatus 1000 according to an embodiment may be a laser processing apparatus. The display device manufacturing apparatus 1000 may be used to process the shape of a target object SBJ by using a laser beam. For example, an embodiment of the display device manufacturing apparatus 1000 may be used, as described above, to cut the mother substrate MSUB, apply heat to the mother substrate MUSB or a structure on the mother substrate MSUB, or perform patterning during the manufacturing of the display device 10. In some embodiments, the display device manufacturing apparatus 1000 may be used as the laser device LD described above with reference to FIGS. 15 and 20.

In an embodiment, the display device manufacturing apparatus 1000 may include a stage 1100, a processing laser unit 1200, a flatness sensing unit 1300, a common optical system 1400, and a thickness sensing unit 1500.

The stage 1100 may provide a space or a surface on which the target object SBJ can be placed or disposed. The target object SBJ may be disposed on the stage 1100 during the manufacturing process of the display device. The target object SBJ may include the mother substrate MSUB of the display device manufacturing method S1 described above.

The processing laser unit 1200 may generate a processing laser capable of processing the target object SBJ. The processing laser unit 1200 may include a processing laser generator 1210 and a processing laser optical system 1220.

The processing laser generator 1210 may generate a first laser LSR1. The processing laser generator 1210 may include a light source that generates the first laser LSR1. The processing laser generator 1210 may emit the first laser LSR1 continuously or discontinuously. The wavelength, amplitude, energy density, or the like of the first laser LSR1 may be adjusted by the processing laser generator 1210.

The first laser LSR1 may be the processing laser. The processing laser may apply energy directly to the target object SBJ to process the shape of the target object SBJ.

The processing laser optical system 1220 may be disposed to one side of the processing laser generator 1210. The processing laser optical system 1220 may transform the form of the first laser LSR1. In an embodiment, for example, the processing laser optical system 1220 may convert the shape, size, or focusing characteristics of the first laser LSR1 to adjust the initial form of the first laser LSR1 to a final processing laser form.

The processing laser optical system 1220 may include at least one optical element. In an embodiment, for example, the processing laser optical system 1220 may include a beam converter and a scanner.

In some embodiments, the beam converter of the processing laser optical system 1220 may convert the first laser LSR1 in the form of a Gaussian beam into a Bessel beam. The beam converter may include at least one selected from an axicon lens or a relay lens. The first laser LSR1 may be converted from a Gaussian beam form into a Bessel beam form by the axicon lens, and may be converted into a ring-shaped Bessel beam by the relay lens.

In some embodiments, the scanner in the processing laser optical system 1220 may change the traveling direction of the first laser LSR1. In an embodiment, for example, the scanner may be a type of galvanometer scanner or galvo scanner. The scanner may be provided with two mirrors having different axes of rotation, but is not limited thereto. The flatness sensing unit 1300 may measure the flatness of the stage 1100 and the target object SBJ. The flatness sensing unit 1300 may measure the flatness of the target object SBJ by measuring a distance to the contact surface (i.e., the bottom surface of the target object SBJ and the top surface of the stage 1100) between the target object SBJ and the stage 1100. In some embodiments, the flatness sensing unit 1300 may include an autofocus sensor.

The flatness sensing unit 1300 may include a sensing laser generator 1310, a sensing laser optical system 1320, and a sensing laser sensor 1330.

The sensing laser generator 1310 may generate a second laser LSR2. The sensing laser generator 1310 may include a light source that generates the second laser LSR2. The sensing laser generator 1310 may emit the second laser LSR2 continuously or discontinuously. The wavelength, amplitude, energy density, or the like of the second laser LSR2 may be adjusted by the sensing laser generator 1310.

The second laser LSR2 may be a first sensing laser. The first sensing laser may be reflected from the target object SBJ and provide information about the shape of the target object SBJ (e.g., information about flatness) to the sensing laser sensor 1330.

The sensing laser optical system 1320 may be disposed to one side of the sensing laser generator 1310. The sensing laser optical system 1320 may transform the form of the second laser LSR2. In an embodiment, for example, the sensing laser optical system 1320 may convert the shape, size, or focusing characteristics of the second laser LSR2 in order to adjust the initial form of the second laser LSR2 to a final sensing laser form.

The sensing laser optical system 1320 may include at least one optical element. In an embodiment, for example, the sensing laser optical system 1320 may include a condensing lens.

In some embodiments, the condensing lens of the sensing laser optical system 1320 may focus the second laser LSR2 onto a target point to be sensed. Accordingly, the sensing accuracy of the flatness sensing unit 1300 may be improved.

The sensing laser sensor 1330 may receive the second laser LSR2. In an embodiment, for example, the sensing laser sensor 1330 may receive the second laser LSR2 reflected back from the target object SBJ. The sensing laser sensor 1330 may collect information about the shape of the target object SBJ from the received second laser LSR2.

In some embodiments, the wavelength of the first laser LSR1 reaching the target object SBJ may differ from the wavelength of the second laser LSR2 reaching the target object SBJ. In an embodiment, for example, the wavelength of the first laser LSR1 reaching the target object SBJ may be in a range of about 950 nm to about 1050 nm, while the wavelength of the second laser LSR2 reaching the target object SBJ may be in a range of about 800 nm to about 900 nm.

In some embodiments, the pulse energy of the first laser LSR1 reaching the target object SBJ may be greater than the pulse energy of the second laser LSR2 reaching the target object SBJ. In an embodiment, for example, the pulse energy of the first laser LSR1 reaching the target object SBJ may be in a range of about 10 μJ to about 500 μJ, while the pulse energy of the second laser LSR2 reaching the target object SBJ may be in a range of about 10 nanojoules (nJ) to about 1 μJ.

In some embodiments, the pulse width of the first laser LSR1 reaching the target object SBJ may be greater than the pulse width of the second laser LSR2 reaching the target object SBJ. In an embodiment, for example, the pulse width of the first laser LSR1 reaching the target object SBJ may be in a range of about 300 fs to about 10 ps, and the pulse width of the second laser LSR2 reaching the target object SBJ may be in a range of about 50 fs to about 500 fs. In another embodiment, the second laser LSR2 may be a continuous wave.

The common optical system 1400 may adjust the path and form of each of the first laser LSR1 and the second laser LSR2. By In an embodiment, the display device manufacturing apparatus 1000 may include the common optical system capable of adjusting both the path and form of the first laser LSR1 and the second laser LSR2 such that the sensing accuracy of the flatness sensing unit 1300 may be improved.

The common optical system 1400 may include a beam splitter 1410, an objective lens 1420, an objective driver 1430, and a beam dump 1440.

The beam splitter 1410 may be disposed at one side of the processing laser optical system 1220 and one side of the sensing laser optical system 1320. In an embodiment, for example, a first surface 1410a of the beam splitter 1410 may be connected to one side of the processing laser optical system 1220, and a second surface 1410b of the beam splitter 1410 may be connected to one side of the sensing laser optical system 1320. In some embodiments, the first laser LSR1 may be incident on the first surface 1410a of the beam splitter 1410 in a vertical direction, and the second laser LSR2 may be incident on the second surface 1410b of the beam splitter 1410 in a horizontal direction. However, although the incident directions of the first laser LSR1 and the second laser LSR2 may differ from each other, the first laser LSR1 is not limited to being incident in the vertical direction and the second laser LSR2 is not limited to being incident in the horizontal direction.

The beam splitter 1410 may partially transmit and partially reflect each of the first laser LSR1 and the second laser LSR2. The beam splitter 1410 may include a prism or a half mirror.

The objective lens 1420 may be disposed to one side of the beam splitter 1410 where the processing laser unit 1200 and the flatness sensing unit 1300 are not positioned. In an embodiment, for example, the objective lens 1420 may be connected to a third surface 1410c of the beam splitter 1410.

The objective lens 1420 may adjust the focal distance of the first laser LSR1 emitted from the processing laser optical system 1220 and the second laser LSR2 emitted from the sensing laser optical system 1320, thereby focusing each of the first laser LSR1 and the second laser LSR2 onto the target object SBJ.

The objective lens 1420 may include at least one lens. In an embodiment where the objective lens 1420 includes a plurality of lenses, the plurality of lenses may have a single effective focal distance and may function as a single virtual lens.

The objective driver 1430 may adjust the relative position of the objective lens 1420 with respect to the stage 1100 (or the target object SBJ). In an embodiment, for example, the objective driver 1430 may provide a driving force to the objective lens 1420 to adjust a distance between the objective lens 1420 and the stage 1100 (or the target object SBJ). Accordingly, the focal positions of the first laser LSR1 and second laser LSR2 formed on the target object SBJ may be adjusted.

The beam dump 1440 may be disposed to one side of the beam splitter 1410 where the processing laser unit 1200, the flatness sensing unit 1300, and the objective lens 1420 are not positioned. In an embodiment, for example, the beam dump 1440 may be connected to a fourth surface 1410d of the beam splitter 1410.

The beam dump 1440 may absorb each of the first laser LSR1 and second laser LSR2 dispersed from the beam splitter 1410. A portion of the first laser LSR1 and the second laser LSR2 dispersed from the beam splitter 1410 may move in a direction other than toward the objective lens 1420. The beam dump 1440 may absorb such unnecessary energy of the first laser LSR1 and the second laser LSR2, thereby preventing damage to the display device manufacturing apparatus 1000.

The thickness sensing unit 1500 may measure the thickness of the target object SBJ. The thickness sensing unit 1500 may measure the thickness of the target object SBJ by measuring a distance to the top surface of the target object SBJ and a distance to the bottom surface of the target object SBJ. The thickness sensing unit 1500 may include a sensing laser generator and a sensing laser sensor, separately from the flatness sensing unit 1300.

The sensing laser generator of the thickness sensing unit 1500 may generate a third laser LSR3, and the sensing laser sensor of the thickness sensing unit 1500 may receive the third laser LSR3. The third laser LSR3 may be a second sensing laser. The second sensing laser may be reflected from the target object SBJ and provide information about the shape of the target object SBJ (e.g., information about thickness) to the sensing laser sensor of the thickness sensing unit 1500.

In some embodiments, the thickness sensing unit 1500 may include a confocal sensor.

In an embodiment, the display device manufacturing apparatus 1000 may include the flatness sensing unit 1300 and the thickness sensing unit 1500 such that the focal distance of the processing laser may be corrected or adjusted in real time. Accordingly, the mass production quality and yield of the display device manufactured using the display device manufacturing apparatus 1000 may be improved.

In an embodiment, for example, the focal point of the first laser LSR1 may be formed at a specific position in the thickness direction of the target object SBJ. As described above with reference to FIG. 15 and the like, the laser spot SPOT (see FIG. 15) may be desired to be accurately formed at a target position. In some embodiments, the thickness of the target object SBJ may vary at each arbitrary point in the horizontal direction, and the flatness of the target object SBJ may also vary at each arbitrary point in the horizontal direction depending on the flatness of the stage 1100.

The display device manufacturing apparatus 1000 according to an embodiment may correct the flatness deviation of the target object SBJ through the flatness sensing unit 1300 and the thickness deviation of the target object SBJ through the thickness sensing unit 1500 in real time, thereby allowing the focal point of the first laser LSR1 to be accurately formed at a target position.

Hereinafter, an embodiment of a process in which the display device manufacturing apparatus 1000 senses the thickness deviation and flatness deviation of the target object SBJ in real time and corrects the focal distance of the processing laser will be described.

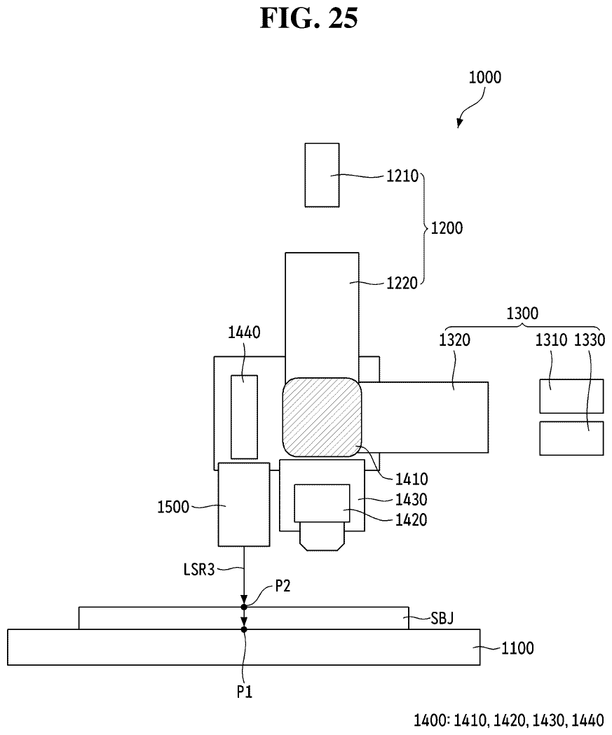

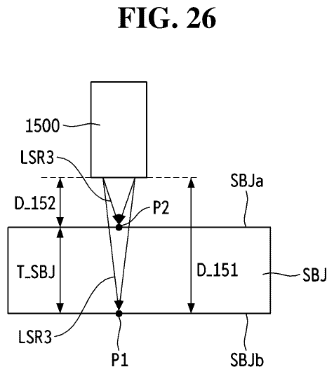

FIG. 25 is a cross-sectional view illustrating an operating state of a thickness sensing unit according to an embodiment. FIG. 26 is a cross-sectional view illustrating a thickness sensing method of a thickness sensing unit according to an embodiment.

Referring to FIGS. 25 and 26, in an embodiment, the thickness sensing unit 1500 may form the focal point of the third laser LSR3 at each of a first point P1 located on a bottom surface SBJb of the target object SBJ and a second point P2 located on a top surface SBJa of the target object SBJ. The first point P1 and the second point P2 may be two points located on a straight line in the thickness direction of the target object SBJ.

The thickness sensing unit 1500 may measure a distance D_151 to the first point P1 and a distance D_152 to the second point P2. The thickness sensing unit 1500 may measure a thickness T_SBJ of the target object SBJ by using the difference between the distance D_152 to the second point P2 and the distance D_151 to the first point P1.

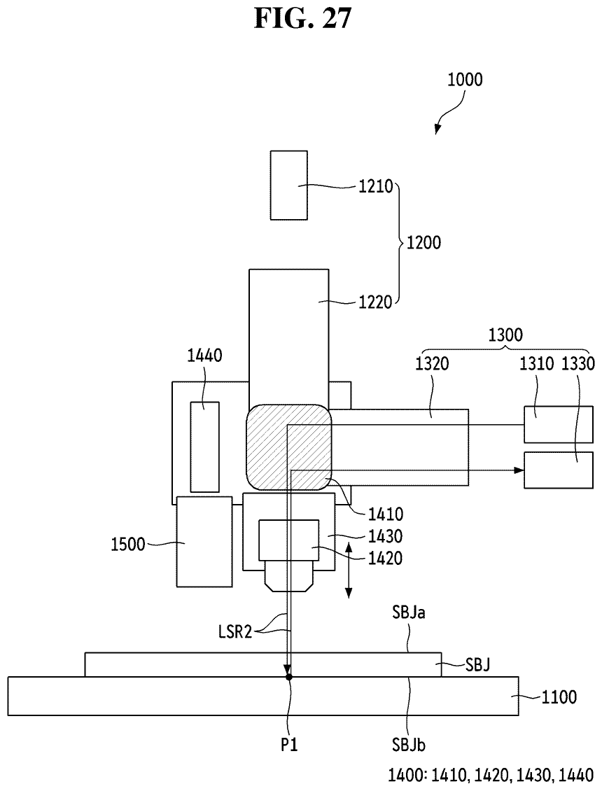

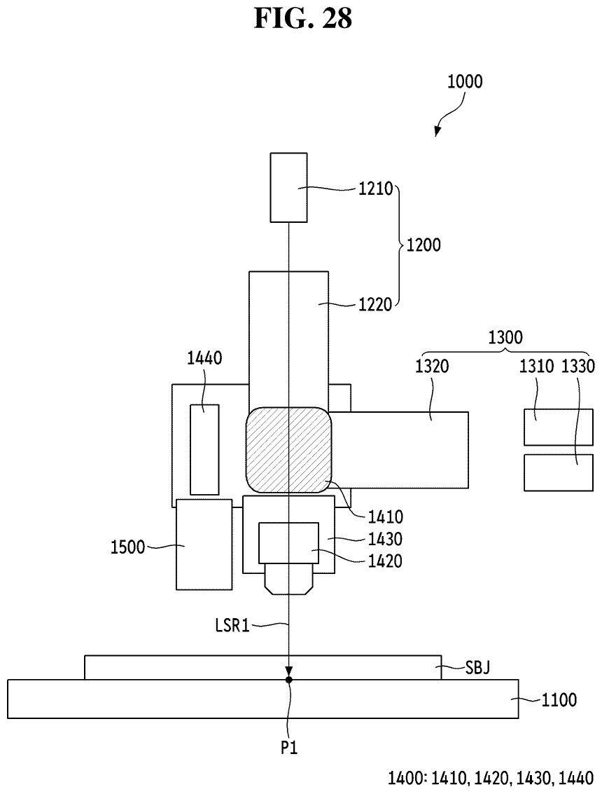

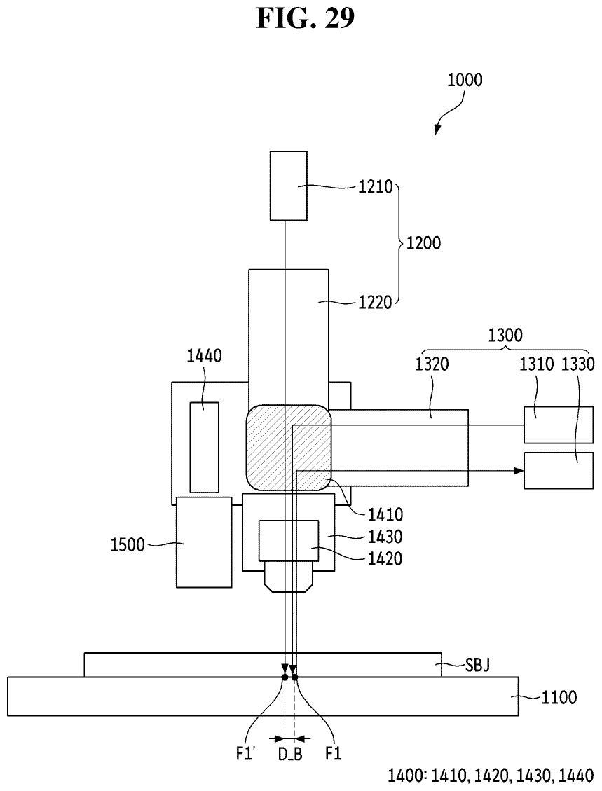

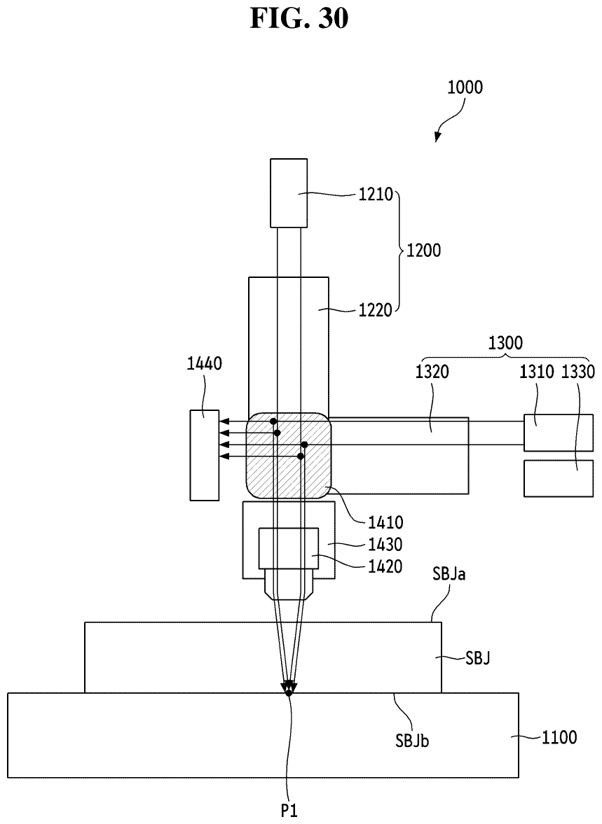

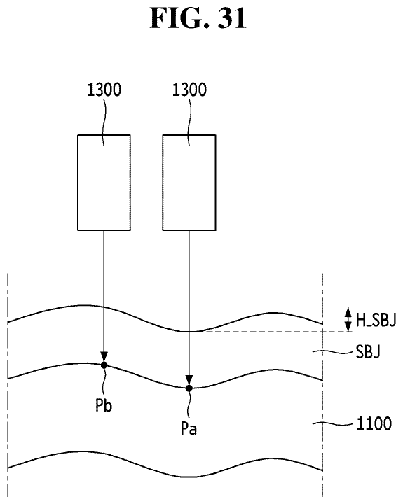

FIG. 27 is a cross-sectional view illustrating an operating state of a flatness sensing unit according to an embodiment. FIG. 28 is a cross-sectional view illustrating an operating state of a processing laser unit according to an embodiment. FIG. 29 is a cross-sectional view illustrating operating states of a flatness sensing unit and a processing laser unit according to an embodiment. FIG. 30 is a cross-sectional view illustrating the traveling paths of a sensing laser of a flatness sensing unit and a processing laser of a processing laser unit according to an embodiment. FIG. 31 is a cross-sectional view illustrating a flatness sensing method of a flatness sensing unit according to an embodiment.

Referring to FIGS. 27 to 31 in addition to FIGS. 25 and 26, in an embodiment, the flatness sensing unit 1300 may form the focal point of the second laser LSR2 at the first point P1 located on the bottom surface SBJb of the target object SBJ. The flatness sensing unit 1300 may measure a distance to a point where the bottom surface SBJb of the target object SBJ and the top surface of the stage 1100 come into contact with each other, in order to measure the flatness of the target object SBJ.

The sensing laser generator 1310 of the flatness sensing unit 1300 may generate the second laser LSR2. The second laser LSR2 may pass through the sensing laser optical system 1320 of the flatness sensing unit 1300, and the beam splitter 1410 and the objective lens 1420 of the common optical system 1400, and be reflected from the target object SBJ. The reflected second laser LSR2 may pass again through the objective lens 1420 and the beam splitter 1410 of the common optical system 1400 and the sensing laser optical system 1320 of the flatness sensing unit 1300 to reach the sensing laser sensor 1330.

The flatness sensing unit 1300 may measure a distance between the flatness sensing unit 1300 and the first point P1 of the target object SBJ. The distance between the flatness sensing unit 1300 and the first point P1 of the target object SBJ may be measured based on the traveling distance (e.g., a distance along an optical path) of the second laser LSR2. In an embodiment, for example, the distance between the flatness sensing unit 1300 and the first point P1 of the target object SBJ may be half of the traveling distance of the second laser LSR2.

As shown in FIG. 28, the processing laser unit 1200 may form the focal point of the first laser LSR1 at an arbitrary point in the thickness direction of the target object SBJ. In an embodiment, for example, as shown in the drawing, the processing laser unit 1200 may form the focal point of the first laser LSR1 at the first point P1 located on the bottom surface SBJb of the target object SBJ. However, the disclosure is not limited thereto, and as described above with reference to FIG. 15 and the like, the focal point of the first laser LSR1 may be formed at an arbitrary point in the thickness direction of the target object SBJ, similarly to the laser spot SPOT, for shape control (e.g., cutting of the mother substrate MSUB) of the target object SBJ. Hereinafter, a case where the focal point of the first laser LSR1 is located on the bottom surface SBJb of the target object SBJ will be described as an example.

The processing laser generator 1210 of the processing laser unit 1200 may generate the first laser LSR1. The first laser LSR1 may pass through the processing laser optical system 1220 of the processing laser unit 1200, and the beam splitter 1410 and the objective lens 1420 of the common optical system 1400 to reach the target object SBJ.

The first laser LSR1 that reaches the target object SBJ may process the shape of the target object SBJ as in the display device manufacturing method S1 (see FIG. 13) described with reference to FIG. 15 and the like.

When processing the shape of the target object SBJ, the focal point of the first laser LSR1 may be formed not only at the first point P1 located on the bottom surface SBJb of the target object SBJ, but also at one point between the top surface SBJa and the bottom surface SBJb in the thickness direction of the target object SBJ, and at one point located on the top surface SBJa.

In an embodiment, before processing the shape of the target object SBJ using the first laser LSR1, the focal distance of the first laser LSR1 may be corrected or adjusted in real time by using the thickness of the target object SBJ measured by the thickness sensing unit 1500 and the flatness measured by the flatness sensing unit 1300.

In an embodiment, for example, the focal distance of the first laser LSR1 may be corrected in real time by adding a difference between the thickness of the target object SBJ measured by the thickness sensing unit 1500 and the initially set thickness of the target object SBJ, and a difference between the distance to the bottom surface SBJb of the target object SBJ measured by the flatness sensing unit 1300 and an initially set distance to the bottom surface SBJb of the target object SBJ.

The method of measuring the thickness of the target object SBJ using the thickness sensing unit 1500 has been described with reference to FIG. 26, and the method of measuring the flatness of the target object SBJ using the flatness sensing unit 1300 will be described.

As shown in FIG. 31, the flatness of the target object SBJ may be affected by the flatness of the stage 1100. Alternatively, the flatness of the target object SBJ may vary due to the curvature of the target object SBJ itself.

The flatness sensing unit 1300 may measure distances to a first measurement point Pa and a second measurement point Pb, which are at different positions on the bottom surface of the target object SBJ. The first measurement point Pa may serve as a reference point for measuring the initially set distance. The second measurement point Pb may be a target point for real-time correction, where the focal point of the first laser LSR1 will be formed.

In an embodiment, for example, the flatness sensing unit 1300 may measure a difference H_SBJ between the distance to the first measurement point Pa and the distance to the second measurement point Pb to ensure that the focal point of the first laser LSR1 is formed at the second measurement point Pb. The focal position of the first laser LSR1 may be corrected by the difference H_SBJ between the distance to the first measurement point Pa and the distance to the second measurement point Pb.

If there is a difference between the thickness of the target object SBJ measured by the thickness sensing unit 1500 and the initially set thickness of the target object SBJ, the focal position of the first laser LSR1 may be corrected by adding the difference between the thickness of the target object SBJ measured by the thickness sensing unit 1500 and the initially set thickness of the target object SBJ, to the difference between the distance to the bottom surface SBJb of the target object SBJ measured by the flatness sensing unit 1300 and the initially set distance to the bottom surface SBJb of the target object SBJ.

in an embodiment, the focal distance correction of the first laser LSR1 may be performed by the objective driver 1430. In an embodiment, for example, the objective driver 1430 may adjust the height of the objective lens 1420 to correct the focal distance of the first laser LSR1.

The display device manufacturing apparatus 1000 according to an embodiment may improve sensing accuracy by using a coaxial measurement method. In an embodiment, for example, as shown in FIG. 29, the first laser LSR1 generated from the processing laser unit 1200 and the second laser LSR2 generated from the flatness sensing unit 1300 may reach the target object SBJ along optical paths of the same axis through the common optical system 1400.

Accordingly, a distance D_B between a focal position F1′ of the first laser LSR1 and a focal position F1 of the second laser LSR2 may be minimized. In some embodiments, the distance D_B between the focal position F1′ of the first laser LSR1 and the focal position F1 of the second laser LSR2 may be less than or equal to about 50 μm.

Additionally, since both the first laser LSR1 and the second laser LSR2 pass through the common optical system 1400, the focal distance and other characteristics of the first laser LSR1 and the second laser LSR2 may be adjusted simultaneously by manipulating the beam splitter 1410 or the objective lens 1420 of the common optical system 1400, and correction errors caused by individual adjustments may be minimized.

In an embodiment, as shown in FIG. 30, a portion of the first laser LSR1 may be transmitted through the beam splitter 1410 and incident on the objective lens 1420, while a portion of the second laser LSR2 may be reflected by the beam splitter 1410 and incident on the objective lens 1420. In such an embodiment, another portion of the first laser LSR1 may be reflected by the beam splitter 1410 and may not be incident on the objective lens 1420, while another portion of the second laser LSR2 may be transmitted through the beam splitter 1410 and may not be incident on the objective lens 1420.

As such, the unnecessary portions of the first laser LSR1 and the second laser LSR2 that is not desired to be incident from the beam splitter 1410 to the objective lens 1420 may be incident on the beam dump 1440. The beam dump 1440 may absorb the energy of the first laser LSR1 and the second laser LSR2 to prevent damage to the display device manufacturing apparatus 1000.

Hereinafter, a process of measuring the thickness and flatness of the target object SBJ and correcting the position of the processing laser, using an embodiment of the display device manufacturing apparatus 1000, will be described.

First, as shown in FIGS. 25 and 26, the thickness of the target object SBJ may be measured by radiating the third laser LSR3 to the top and bottom surfaces of the target object SBJ.

Next, as shown in FIG. 27, the flatness of the target object SBJ may be measured by radiating the second laser LSR2 to the bottom surface of the target object SBJ.

Then, based on the measured thickness and flatness of the target object SBJ, the objective driver 1430 may adjust the position of the objective lens 1420, thereby correcting the focal position of the first laser LSR1.

Thereafter, as shown in FIG. 28, the first laser LSR1 may be radiated to the target object SBJ to form a cutting line.

Although the process of measuring the flatness of the target object SBJ, the process of correcting the focal position of the first laser LSR1, and the process of forming the cutting line using the first laser LSR1 have been described as proceeding sequentially, the disclosure is not limited thereto.

As shown in FIGS. 29 and 30, the process of measuring the flatness, the process of correcting the focal position of the first laser LSR1, and the process of forming the cutting line using the first laser LSR1 may proceed simultaneously. Here, proceeding simultaneously means that each process is performed within a range of several microseconds (μs) to several hundred microseconds (μs).

In an embodiment, for example, after the thickness of the target object SBJ is measured by radiating the third laser LSR3 at a specific point, the second laser LSR2 may track the curvature of the bottom surface of the target object SBJ in real time at the corresponding point, and based on the real-time tracked information, the objective driver 1430 may correct the position of the objective lens 1420 to correct the position of the first laser LSR1, thereby allowing the cutting line of the first laser LSR1 to be corrected in real time as well.

By using a coaxial measurement method in which the first laser LSR1 and the second laser LSR2 are incident on the same objective lens 1420 through the beam splitter 1410 of the common optical system 1400, the display device manufacturing apparatus 1000 according to an embodiment may simultaneously perform the height correction of the first laser LSR1 due to the flatness of the target object SBJ, and the cutting process. That is, since the focal position of the first laser LSR1 and the focal position of the second laser LSR2 are synchronized by the common optical system 1400, when the second laser LSR2 tracks the curvature of the bottom surface of the target object SBJ and adjusts the position of the objective lens 1420 in real time, the focal position of the first laser LSR1 may also be adjusted due to the synchronization.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display device, comprising:
a stage;
a processing laser unit which generates a first laser toward the stage;
a flatness sensing unit which generates a second laser toward the stage;
a common optical system disposed in optical paths of the first laser and the second laser; and
a thickness sensing unit which generates a third laser toward the stage,
wherein the common optical system comprises an objective lens through which both the first laser and the second laser pass.

2. The apparatus of claim 1, wherein the common optical system further comprises a beam splitter which transmits at least a portion of each of the first laser and the second laser and reflects another portion of each of the first laser and the second laser,
the processing laser unit is disposed on one side of a first surface of the beam splitter, and
the flatness sensing unit is disposed on one side of a second surface of the beam splitter, which is different from the first surface thereof.

3. The apparatus of claim 2, wherein a direction in which the first laser is incident on the beam splitter is different from a direction in which the second laser is incident on the beam splitter.

4. The apparatus of claim 2, wherein the objective lens is disposed on one side of a third surface of the beam splitter, which is different from the first surface and the second surface thereof.

5. The apparatus of claim 2, wherein the beam splitter causes the first laser and the second laser, which are incident from different directions, to be emitted in a same direction.

6. The apparatus of claim 5, wherein the common optical system further comprises a beam dump which absorbs at least a portion of the first laser and the second laser, and
the beam dump is disposed on one side of a fourth surface of the beam splitter, which is different from the first to third surfaces thereof.

7. The apparatus of claim 2, wherein the beam splitter comprises a prism or a half mirror.

8. The apparatus of claim 1, wherein the common optical system further comprises an objective driver which provides a driving force to the objective lens.

9. The apparatus of claim 8, wherein the objective driver moves the objective lens to adjust focal positions of the first laser and the second laser.

10. The apparatus of claim 1, wherein a separation distance between a focal position of the first laser and a focal position of the second laser is less than or equal to about 50 μm.

11. The apparatus of claim 1, wherein a focal position of the second laser is located on a top surface of the stage.

12. The apparatus of claim 1, wherein a focal position of the third laser is located on top and bottom surfaces of a target object.

13. The apparatus of claim 1, wherein the flatness sensing unit comprises an autofocus sensor.

14. The apparatus of claim 1, wherein the thickness sensing unit comprises a confocal sensor.

15. The apparatus of claim 1, wherein a wavelength of the first laser is greater than a wavelength of the second laser.

16. A method for manufacturing a display device, the method comprising:
measuring a thickness of a mother substrate by irradiating top and bottom surfaces of the mother substrate with a first sensing laser;
measuring flatness of the mother substrate by irradiating the bottom surface of the mother substrate with a second sensing laser;
correcting a focal position of a processing laser by adjusting a position of an optical system based on the measured thickness and flatness of the mother substrate; and
forming a cutting line by irradiating the mother substrate with the processing laser,
wherein the measuring the flatness, the correcting the focal position of the processing laser, and the forming the cutting line are performed simultaneously.

17. The method of claim 16, wherein both the second sensing laser and the processing laser pass through the optical system.

18. The method of claim 16, wherein the measuring the flatness and the correcting the focal position of the processing laser comprise tracking, by the second sensing laser, a curvature of the bottom surface of the mother substrate in real time to adjust a position of the optical system, and
the focal position of the processing laser is adjusted together with the position of the optical system.

19. The method of claim 16, wherein the focal position of the processing laser is synchronized with a focal position of the second sensing laser through the optical system,
the position of the optical system is corrected based on a change in the focal position of the second sensing laser, and
the focal position of the processing laser is corrected together with a correction of the position of the optical system.

20. An electronic device comprising a display device,
wherein the display device comprising:
a stage;
a processing laser unit which generates a first laser toward the stage;
a flatness sensing unit which generates a second laser toward the stage;
a common optical system disposed in optical paths of the first laser and the second laser; and
a thickness sensing unit which generates a third laser toward the stage, and
wherein the common optical system comprises an objective lens through which both the first laser and the second laser pass.
